(19) United States
(12) Patent Application Publication
(10) Pub. No.: US 2026/0136706 A1
(43) Pub. Date: May 14, 2026

(54) STRUCTURED ULTRAVIOLET LIGHT SHIELDING ARTICLES AND SOLAR ARRAYS INCLUDING THE SAME

(71) Applicant: 3M INNOVATIVE PROPERTIES COMPANY, St. Paul, MN (US)

(72) Inventors: Sean M. Sweetnam, Minneapolis, MN (US); David J. Rowe, Roseville, MN (US); Daniel M. Pierpont, North St. Paul, MN (US); Mark D. Weigel, Hugo, MN (US); Kevin D. Hagen, St. Paul, MN (US); Scott J. Jones, Circle Pines, MN (US); Kevin W. Gotrik, Hudson, WI (US); James A. Phipps, River Falls, WI (US); Mark B. O'Neill, Stillwater, MN (US)

(21) Appl. No.: 19/118,500

(22) PCT Filed: Nov. 14, 2023
(86) PCT No.: PCT/IB2023/061489

§ 371 Date: Apr. 4, 2025

Related U.S. Application Data
(60) Provisional application No. 63/426,190, filed on Nov. 17, 2022.
(60) Provisional application No. 63/434,423, filed on Dec. 21, 2022.
(60) Provisional application No. 63/444,360, filed on Feb. 9, 2023.
(60) Provisional application No. 63/583,953, filed on Sep. 20, 2023.

(51) Int. Cl. H10F 77/30; G02B 1/14; G02B 5/20; H10F 77/70

(52) U.S. Cl. CPC H10F 77/311; G02B 1/14; G02B 5/208; H10F 77/334; H10F 77/703

(57) ABSTRACT

Structured ultraviolet light shielding articles are provided. A structured ultraviolet light shielding article includes a microstructured film having a first major surface and an opposing second major surface, in which the first major surface includes microstructures projecting therefrom; and a multilayer optical film disposed on the microstructures. At least some of the microstructures each has a surface whose slope causes light that is normally incident to the first major surface of the microstructured film to intercept the first major surface or the surface of at least one other microstructure after reflection. The multilayer optical film is comprised of one or more alternating first and second inorganic optical layers collectively reflecting and absorbing light that is normally incident to the first major surface of the microstructured film, an average of at least 50, 60, 70, 80, 90, or 95 percent of incident ultraviolet light over at least a 30-nanometer wavelength reflection bandwidth in a wavelength range from 190 nanometers (nm) to 400 nm. Solar arrays including structured ultraviolet light shielding articles are also provided.

### BACKGROUND

There is a class of telecommunications network with infrastructure provided by constellations of thousands of small satellites deployed in low earth orbit. These satellites require power via arrays of solar cells mounted to their frames and these solar arrays in turn require protection from the harsh environment of low earth orbit.

The devices typically operate at altitudes ranging from 20-2000 km, where the thin atmosphere absorbs little solar radiation. The high-altitude devices are thus exposed to the more intense AM0 solar spectrum and to a higher intensity of ultraviolet (UV) radiation, particularly UV-C radiation, than is present in the AM1.5 solar spectrum encountered in Earth terrestrial conditions.

### SUMMARY

In a first aspect, a structured ultraviolet light shielding article is provided. The structured ultraviolet light shielding article comprises a) a microstructured film comprising a first major surface and an opposing second major surface, wherein the first major surface comprises a plurality of microstructures projecting therefrom; and b) a multilayer optical film disposed on the plurality of microstructures. At least some of the plurality of microstructures each has a surface whose slope causes light that is normally incident to the first major surface of the microstructured film to intercept the first major surface or the surface of at least one other microstructure after reflection. The multilayer optical film is comprised of one or more alternating first and second inorganic optical layers collectively reflecting and absorbing light that is normally incident to the first major surface of the microstructured film, an average of at least 50, 60, 70, 80, 90, or 95 percent of incident ultraviolet light over at least a 30-nanometer wavelength reflection bandwidth in a wavelength range from 190 nanometers (nm) to 400 nm.

In a second aspect, a solar array is provided. The solar array comprises a structured ultraviolet light shielding article according to the first aspect disposed on an exterior surface of the solar array.

Broadband UV protection is of particular interest. Alternating layers of high and low index materials have been shown to provide UV rejection, but these are often limited to relatively narrow bands of reflection. UV absorbers, on the other hand, are often not able to provide sufficient absorption without thick layers, and many solutions are made with organic absorbers which do not always survive higher energy UVC light and atomic oxygen which are present in low earth orbit.

Ultraviolet light shielding articles according to at least certain embodiments of the present disclosure provide an inorganic based solution that combines the UV absorption of inorganic materials (e.g., titanium oxide or niobium oxide) with a reflection band created by alternating high and low index materials. This creates a broadband UV rejection filter that is durable to both UV and atomic oxygen. This technology could potentially replace the incumbent protective solution for arrays of solar cells in space, cover glass. The use of cover glass is expensive due to the fragile nature of glass slides, as well as the small size of glass slides that require a lot of trimming/laminating.

Various unexpected results and advantages are obtained in exemplary embodiments of the disclosure. One such advantage of exemplary embodiments of the present disclosure is that the combination of UV absorption and reflection in the structured ultraviolet light shielding articles creates a broadband UV rejection filter made from durable inorganic materials that can survive in low earth orbit conditions. Additionally, the use of a microstructured film improves light capture of the article by minimizing light loss due to reflection, as compared to a planar film. The layers can be sputter deposited or evaporated in a roll-to-roll process. As such, a further advantage of exemplary embodiments is to enable a high speed, roll-to-roll continuous production process for the structured ultraviolet light shielding article of the present disclosure.

Various aspects and advantages of exemplary embodiments of the disclosure have been summarized. The above Summary is not intended to describe each illustrated embodiment or every implementation of the present certain exemplary embodiments of the present disclosure.

The Drawings and the Detailed Description that follow more particularly exemplify certain preferred embodiments using the principles disclosed herein.

### BRIEF DESCRIPTION OF THE DRAWINGS

The disclosure may be more completely understood in consideration of the following detailed description of various embodiments of the disclosure in connection with the accompanying figures, in which:

FIG. 1A is a perspective view of a Cartesian coordinate system of a surface that can be utilized to describe various microstructured surfaces;

FIG. 1B is a schematic cross-sectional view of a microstructured film for use in exemplary articles disclosed herein;

FIG. 1C is a schematic cross-sectional view of an exemplary structured ultraviolet light shielding article according to various exemplary embodiments disclosed herein;

FIG. 1D is a scanning electron microscopy (SEM) image of a cross-section of a portion of an exemplary structured ultraviolet light shielding article 10, according to various exemplary embodiments disclosed herein;

FIG. 2 is a schematic cross-sectional view of an exemplary structured ultraviolet light shielding article 10 and an exemplary solar array 30, according to various exemplary embodiments disclosed herein;

FIG. 3 is a perspective view of a microstructured surface comprising a linear array of prisms;

FIG. 4A is a perspective view of a microstructured surface comprising an array of cube corner elements;

FIG. 4B is a perspective view of a microstructured surface comprising an array of pyramid elements;

FIG. 5 is a perspective view of a microstructured surface comprising an array of cones;

FIG. 6 is a perspective view of a microstructured surface comprising a diffraction grating having a bias angle.

FIG. 7 is a perspective view of a microstructured surface comprising an array of inverted pyramids.

In the drawings, like reference numerals indicate like elements. While the above-identified drawings, which may not be drawn to scale, set forth various embodiments of the present disclosure, other embodiments are also contemplated, as noted in the Detailed Description. In all cases, this disclosure describes the presently disclosed disclosure by way of representation of exemplary embodiments and not by express limitations. It should be understood that numerous other modifications and embodiments can be devised by those skilled in the art, which fall within the scope and spirit of this disclosure.

### DETAILED DESCRIPTION

For the following Glossary of defined terms, these definitions shall be applied for the entire application, unless a different definition is provided in the claims or elsewhere in the specification.

### Glossary

Certain terms are used throughout the description and the claims that, while for the most part are well known, may require some explanation. It should be understood that:

The term “fluoropolymer” refers to any organic polymer containing fluorine.

The term “nonfluorinated” means not containing fluorine.

The terms “(co)polymer” or “(co)polymers” includes homo(co)polymers and (co)polymers, as well as homo(co)polymers or (co)polymers that may be formed in a miscible blend, (e.g., by coextrusion or by reaction, including, (e.g., transesterification)). The term “(co)polymer” includes random, block and star (co)polymers.

As used herein, “adjacent” encompasses both in direct contact (e.g., directly adjacent) and having one or more intermediate layers present between the adjacent materials.

As used herein, “incident” with respect to light refers to the light falling on or striking a material.

The term “crosslinked” (co)polymer refers to a (co)polymer whose (co)polymer chains are joined together by covalent chemical bonds, usually via crosslinking molecules or groups, to form a network (co)polymer. A crosslinked (co)polymer is generally characterized by insolubility but may be swellable in the presence of an appropriate solvent.

The term “cure” refers to a process that causes a chemical change, (e.g., a reaction that creates a covalent bond to solidify a multilayer film layer or increase its viscosity.

The term “cured (co)polymer” includes both crosslinked and uncrosslinked (co)polymers.

The term “metal” includes a pure metal or a metal alloy.

The term “film” or “layer” refers to a single stratum within a multilayer film.

The term “substrate” encompasses films and layers, including microstructured films/layers.

The term “(meth)acryl” or “(meth)acrylate” with respect to a monomer, oligomer, (co)polymer or compound means a vinyl-functional alkyl ester formed as the reaction product of an alcohol with an acrylic or a methacrylic acid.

The term “optically clear” refers to an article in which there is no visibly noticeable distortion, haze or flaws as detected by the naked eye at a distance of about 1 meter, preferably about 0.5 meters.

The term “optical thickness” when used with respect to a layer refers to the physical thickness of the layer times its in-plane index of refraction.

The term “vapor coating” or “vapor depositing” means applying a coating to a substrate surface from a vapor phase, for example, by evaporating and subsequently depositing onto the substrate surface a precursor material to the coating or the coating material itself. Exemplary vapor coating processes include, for example, physical vapor deposition (PVD), chemical vapor deposition (CVD), and combinations thereof.

By using terms of orientation such as “atop”, “on”, “over,” “covering”, “uppermost”, “underlying” and the like for the location of various elements in the disclosed coated articles, we refer to the relative position of an element with respect to a horizontally-disposed, upwardly-facing substrate. However, unless otherwise indicated, it is not intended that the substrate or articles should have any particular orientation in space during or after manufacture, or in interpreting the claims.

As used herein, “radiation” refers to electromagnetic radiation unless otherwise specified.

As used herein, “scattering” with respect to wavelengths of light refers to causing the light to depart from a straight path and travel in different directions with different intensities.

As used herein, “reflectance” is the measure of the proportion of light or other radiation striking a surface at normal incidence which is reflected off it. Reflectivity typically varies with wavelength and is reported as the percent of incident light that is reflected from a surface (0 percent—no reflected light, 100—all light reflected). Reflectivity and reflectance are used interchangeably herein.

As used herein, “reflective” and “reflectivity” refer to the property of reflecting light or radiation, especially reflectance as measured independently of the thickness of a material.

As used herein, “average reflectance” refers to reflectance averaged over a specified wavelength range.

As used herein, “absorption” refers to a material converting the energy of light radiation to internal energy.

As used herein, “absorb” with respect to wavelengths of light encompasses both absorption and scattering, as scattered light also eventually gets absorbed. Absorbance can be measured with methods described in ASTM E903-12 “Standard Test Method for Solar Absorptance, Reflectance, and Transmittance of Materials Using Integrating Spheres”. Absorbance measurements described herein were made by making transmission measurements as previously described and then calculating absorbance using Equation 1.

As used herein, the term “absorbance” with respect to a quantitative measurement refers to the base 10 logarithm of a ratio of incident radiant power to transmitted radiant power through a material. The ratio may be described as the radiant flux received by the material divided by the radiant flux transmitted by the material. Absorbance (A) may be calculated based on internal transmittance (T) according to Equation 1:

$$A = - {log}_{10} T \qquad ( 1 )$$

Emissivity can be measured using infrared imaging radiometers with methods described in ASTM E1933-14 (2018) “Standard Practice for Measuring and Compensating for Emissivity Using Infrared Imaging Radiometers.” According to Kirchhoff's law of thermal radiation, absorbance correlates with emittance. Absorbance, absorptivity, emissivity, and emittance are used interchangeably herein for the same purpose of emitting infrared energy to the atmosphere. Absorb and emit are also used interchangeably herein.

As used herein, the terms “transmittance” and “transmission” refer to the ratio of total transmission of a layer of a material compared to that received by the material, which may account for the effects of absorption, scattering, reflection, etc. Transmittance (T) may range from 0 to 1 or be expressed as a percentage (T %).

As used herein, “transparent” refers to a material (e.g., film or layer) that absorbs less than 20% of light having wavelengths between 350 nm and 2500 nm.

As used herein, “bandwidth” refers to a width of a contiguous band of wavelengths.

As used herein, the term “flexible” refers to being capable of being bent around a roll core with a radius of curvature of up to 7.6 centimeters (cm) (3 inches), in some embodiments up to 6.4 cm (2.5 inches), 5 cm (2 inches), 3.8 cm (1.5 inch), or 2.5 cm (1 inch). In some embodiments, the flexible assembly can be bent around a radius of curvature of at least 0.635 cm (¼ inch), 1.3 cm (½ inch) or 1.9 cm (% inch).

The terms “about” or “approximately” with reference to a numerical value or a shape means+/−five percent of the numerical value or property or characteristic, but expressly includes the exact numerical value.

The term “substantially” with reference to a property or characteristic means that the property or characteristic is exhibited to a greater extent than the opposite of that property or characteristic is exhibited. For example, a substrate that is “substantially” transparent refers to a substrate that transmits more radiation (e.g., visible light) than it fails to transmit (e.g., absorbs and reflects). Thus, a substrate that transmits more than 50% of the visible light incident upon its surface is substantially transparent, but a substrate that transmits 50% or less of the visible light incident upon its surface is not substantially transparent.

As used in this specification and the appended embodiments, the singular forms “a”, “an”, and “the” include plural referents unless the content clearly dictates otherwise. Thus, for example, reference to fine fibers containing “a compound” includes a mixture of two or more compounds. As used in this specification and the appended embodiments, the term “or” is generally employed in its sense including “and/or” unless the content clearly dictates otherwise.

Unless otherwise indicated, all numbers expressing quantities or ingredients, measurement of properties and so forth used in the specification and embodiments are to be understood as being modified in all instances by the term “about.” Accordingly, unless indicated to the contrary, the numerical parameters set forth in the foregoing specification and attached listing of embodiments can vary depending upon the desired properties sought to be obtained by those skilled in the art utilizing the teachings of the present disclosure. At the very least, and not as an attempt to limit the application of the doctrine of equivalents to the scope of the claimed embodiments, each numerical parameter should at least be construed in light of the number of reported significant digits and by applying ordinary rounding techniques.

By definition, the total weight percentages of all ingredients in a composition equals 100 weight percent.

Various exemplary embodiments of the disclosure will now be described. Exemplary embodiments of the present disclosure may take on various modifications and alterations without departing from the spirit and scope of the present disclosure. Accordingly, it is to be understood that the embodiments of the present disclosure are not to be limited to the following described exemplary embodiments but is to be controlled by the limitations set forth in the claims and any equivalents thereof.

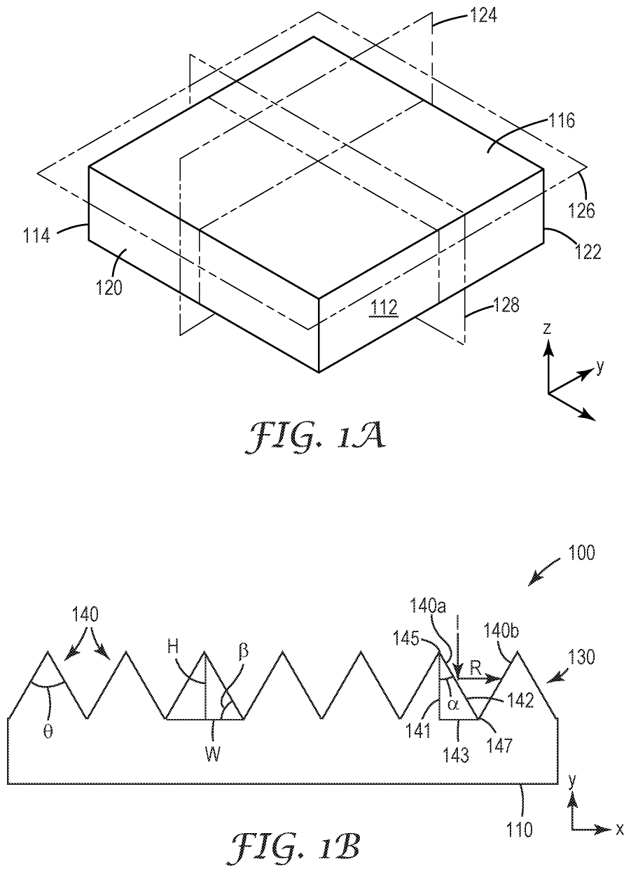

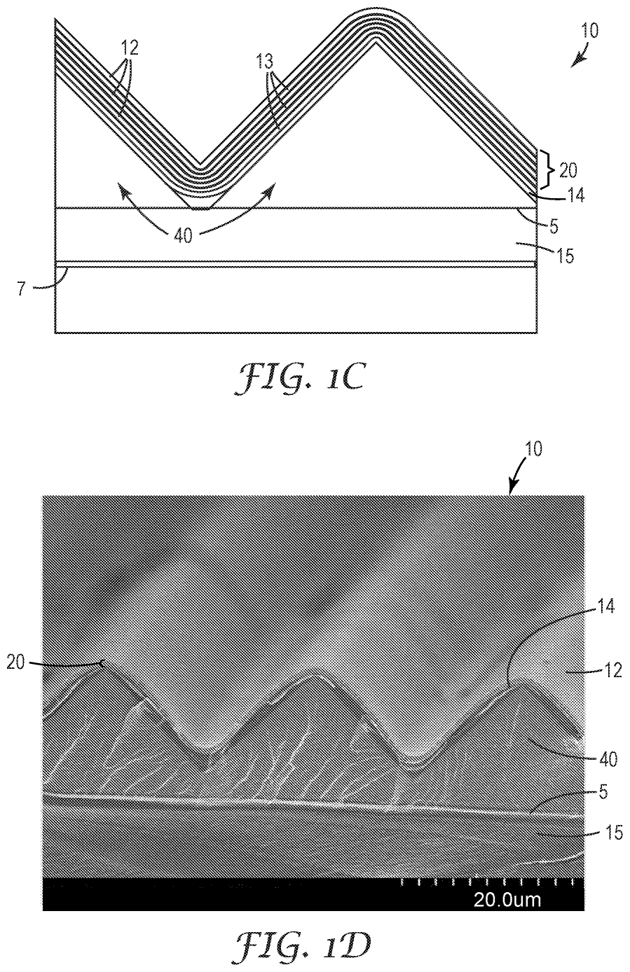

With reference to FIG. 1A, a microstructured surface can be characterized in three-dimensional space by superimposing a Cartesian coordinate system onto its structure. A first reference plane 124 is centered between major surfaces 112 and 114. First reference plane 124, referred to as the y-z plane, has the x-axis as its normal vector. A second reference plane 126, referred to as the x-y plane, extends substantially coplanar with surface 116 and has the z-axis as its normal vector. A third reference plane 128, referred to as the x-z plane, is centered between first end surface 120 and second end surface 122 and has the y-axis as its normal vector.

In some embodiments, the microstructured surfaces are three-dimensional on a macroscale. However, on a microscale (e.g., surface area that includes at least two adjacent microstructures with a valley or channel disposed between the microstructures) the base layer/base member can be considered planar with respect to the microstructures. The width and length of the microstructures are in the x-y plane and the height of the microstructures is in the z-direction. Further, the base layer is parallel to the x-y plane and orthogonal to the z-plane.

### Structured Ultraviolet Light Shielding Article

In a first aspect, a structured ultraviolet light shielding article is provided. The structured ultraviolet light shielding article comprises:
a) a microstructured film comprising a first major surface and an opposing second major surface, wherein the first major surface comprises a plurality of microstructures projecting therefrom, wherein at least some of the plurality of microstructures each has a surface whose slope causes light that is normally incident to the first major surface of the microstructured film to intercept the first major surface or the surface of at least one other microstructure after reflection; and
a multilayer optical film disposed on the plurality of microstructures, wherein the multilayer optical film is comprised of one or more alternating first and second inorganic optical layers collectively reflecting and absorbing light that is normally incident to the first major surface of the microstructured film, an average of at least 50, 60, 70, 80, 90, or 95 percent of incident ultraviolet light over at least a 30-nanometer wavelength reflection bandwidth in a wavelength range from 190 nanometers (nm) to 400 nm.

Referring again to FIG. 1A, by “light normally incident to the first major surface of the microstructured film” is meant light that strikes the first major surface 116 of the microstructured film orthogonal to the reference plane 126 (and parallel to the reference plane 124).

Referring now to FIG. 1B, a schematic cross-sectional view is provided of a microstructured film 100 comprising a plurality of microstructures 140 suitable for use in exemplary articles of the present disclosure. By “a microstructure that has a surface whose slope causes light that is normally incident to the first major surface of the microstructured film to intercept the first major surface or the surface of at least one other microstructure after reflection” is meant that incident light (“I”) that strikes a surface of a microstructure 140a normal to the first major surface 130 of the microstructured film 100, and the microstructure 140a has a slope 142 that causes reflected light (“R”) to intercept either the first major surface of the microstructured film (not shown) or the surface of another microstructure 140b. Per the discussion above with respect to FIG. 1A, the first major surface 130 of the microstructured film 100 is considered parallel to a second major surface 110 of the microstructured film 100. The slope (e.g., sloped surface) 142 of the microstructure 140a is the height 141 of the microstructure 140a divided by the width 143 between the peak (e.g., high end of the sloped surface) 145 and the bottom (e.g., low end of the sloped surface) 147 of the microstructure 140a. Another way to determine slope is using the following formula:

$$m = \frac{Δ y}{Δ x} = tan β$$

wherein m is the slope, Δy is the height of the microstructure, Δx is the width between the peak and the bottom of the microstructure, and angle β is the angle of incline between the sloped surface of the microstructure and the bottom of the microstructure (e.g., as shown in FIG. 1B). For microstructures having a rounded peak, using the tangent of the angle of incline 0 may be a preferable way to determine the slope. An angle alpha (α) can be drawn between the slope 142 and the height 141 of the peak 145. In some cases, the angle α is 45 degrees or less, 40 degrees, 35 degrees, 30 degrees, 25 degrees, 20 degrees, 15 degrees, or 10 degrees or less.

FIG. 1C is a schematic cross-sectional view of a portion of an exemplary structured ultraviolet light shielding article 10 according to at least some exemplary embodiments disclosed herein. The structured ultraviolet light shielding article 10 has a first major surface 5 and an opposing second major surface 7. The first major surface 5 comprises a plurality of microstructures 40 projecting therefrom. The structured ultraviolet light shielding article 10 comprises a multilayer optical film 20 positioned on the plurality of microstructures 40. The multilayer optical film 20 comprises alternating first inorganic optical layers 13 and second inorganic optical layers 12. In this embodiment, the article 10 further includes at least one intermediate layer 14 positioned between the microstructured film 15 and the multilayer optical film 20.

FIG. 1D is a scanning electron microscopy (SEM) image of a cross-section of a portion of an exemplary structured ultraviolet light shielding article 10 according to at least some exemplary embodiments disclosed herein. The structured ultraviolet light shielding article 10 has a first major surface 5. The first major surface 5 comprises a plurality of microstructures 40 projecting therefrom. The structured ultraviolet light shielding article 10 comprises a multilayer optical film 20 positioned on the plurality of microstructures 40. The multilayer optical film 20 comprises alternating first and second inorganic optical layers (the individual layers are too thin to see in the image), a second inorganic optical layer 12 is an outer layer. In this embodiment, the article 10 further includes an intermediate layer 14 positioned between the microstructured film 15 and the multilayer optical film 20.

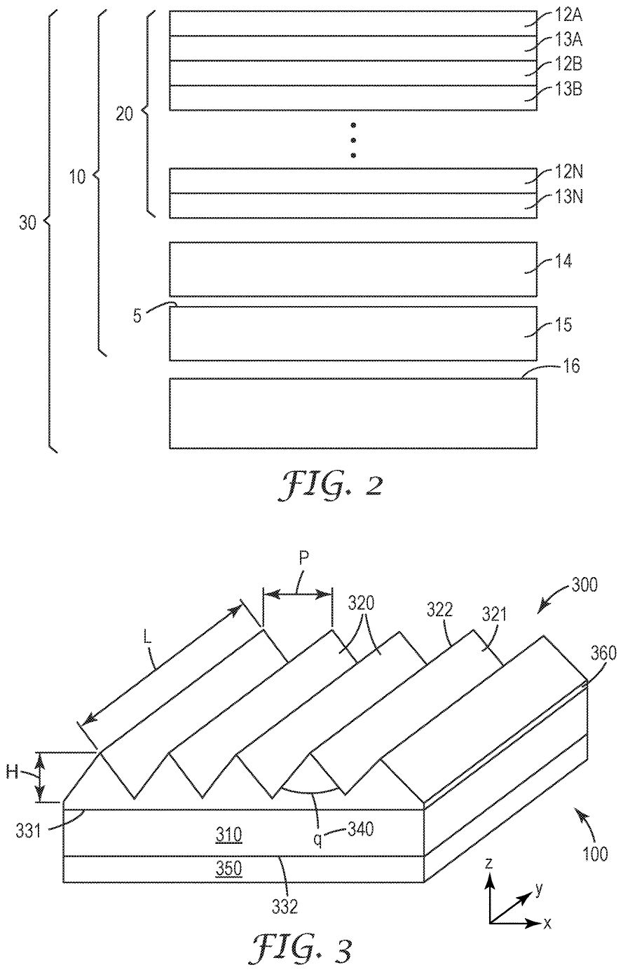

Referring now to FIG. 2, the present disclosure describes structured ultraviolet light shielding articles 10 including a microstructured film 15 having a first major surface 5 and a multilayer optical film 20 positioned on the first major surface 5 of the microstructured film 15. It is noted that for simplicity in this figure, the schematic depiction of the various features does not show any microstructures. In some cases, the multilayer optical film 20 is disposed directly on the first major surface 5 of the microstructured film 15 (e.g., attached directly to the microstructures of the microstructured film 15), whereas in other cases at least one intermediate layer 14 is positioned between the microstructured film 15 and the multilayer optical film 20. Suitable intermediate layers 14 include for instance and without limitation, tie layers, organic base coat layers, barrier coatings, or any combination thereof. As such, the intermediate layer 14 as depicted in FIG. 2 may represent any number of intermediate layers in that location of the overall structure.

The multilayer optical film 20 comprises one or more alternating first inorganic optical layers 13 (A-N) and second inorganic optical layers 12 (A-N).

The alternating first and second inorganic optical layers collectively reflect and absorb light that is normally incident to the first major surface of the microstructured film, an average of at least 50, 60, 70, 80, 90, or 95 percent (preferably at least 80, 90, or 95 percent) of incident ultraviolet light over at least a 30-nanometer wavelength reflection bandwidth in a wavelength range from 190 nanometers (nm) to 400 nm.

In some cases, the alternating first and second inorganic optical layers collectively reflect and absorb light that is normally incident to the first major surface of the microstructured film, an average of at least 60, 70, 80, 90, or 95 percent of incident ultraviolet light over at least a 30-nanometer wavelength reflection bandwidth in a wavelength range from 190 nm to 240 nm, 240 nm to 300 nm, 300 nm to 350 nm, 350 nm to 400 nm, or any combination thereof.

Optionally, the alternating first and second inorganic optical layers collectively reflect and absorb light that is normally incident to the first major surface of the microstructured film, an average of at least 60, 70, 80, 90, or 95 percent of incident ultraviolet light over a greater wavelength reflection bandwidth than at least 30-nanometer, for instance at least a 50-nanometer, 75-nanometer, 100-nanometer, 125-nanometer, 150-nanometer, or 175-nanometer wavelength reflection bandwidth in a wavelength range from 190 nm to 400 nm.

As the alternating first and second inorganic optical layers collectively reflect and absorb, some portion of the incident ultraviolet light may be absorbed and some portion reflected. In some cases, the alternating first and second inorganic optical layers collectively absorb light that is normally incident to the first major surface of the microstructured film, an average of at least 30, 40, 50, 60, 70, 80, 90, or 95 percent of incident light over at least a 30-nanometer wavelength bandwidth in a wavelength range from 190 nm to less than 350 nm. In some cases, the alternating first and second inorganic optical layers collectively reflect light that is normally incident to the first major surface of the microstructured film, an average of at least 30, 40, 50, 60, 70, 80, 90, or 95 percent of incident light over at least a 30-nanometer wavelength bandwidth in a wavelength range from 190 nm to less than 400 nm, 190 nm to 240 nm, 240 nm to 300 nm, 300 nm to 350 nm, 350 nm to less than 400 nm, or any combination thereof.

In select embodiments of the structured ultraviolet light shielding article, the alternating first and second inorganic optical layers collectively transmit light that is normally incident to the first major surface of the microstructured film, an average of at least 50, 60, 70, 80, 90, or 95 percent of incident visible light in a wavelength range from greater than 400 nm to 700 nm.

In select embodiments of the structured ultraviolet light shielding article, the outermost inorganic layer is a second inorganic optical layer (e.g., 12A in FIG. 2) and has a thickness of at least 70 nm. This has the effect of reducing the amount of light reflected off the outer surface of the light shielding article and increases the light transmitted between 400 nm and 700 nm, which is particularly useful when the structured ultraviolet light shielding article is used in a solar array application, to allow visible light to reach the solar cells of the array.

In select embodiments of the structured ultraviolet light shielding article at least one of the first optical layers nearest to the exterior of the film (e.g., 13A in FIG. 2) or nearest to the microstructured film (e.g., 13N in FIG. 2) has a thickness of at most 95%, 90%, 85%, or at most 80% of the other first optical layers. This has the effect of reducing the amount of light reflected off the outer surface of the structured light shielding article between 400 nm and 700 nm, which is particularly useful when the structured ultraviolet light shielding article is used in a solar array application, to allow visible light to reach the solar cells of the array.

In some embodiments, the structured ultraviolet light shielding article (e.g., as a whole) transmits an average of at least 50, 60, 70, 80, 90, or 95 percent of normally incident visible light in a wavelength range from greater than 400 nm to 700 nm. Transmitting such amounts of incident visible light is particularly useful when the ultraviolet light shielding article is used in a solar array application, to allow visible light to reach the solar cells of the array. Additionally, structured ultraviolet light shielding articles according to certain preferred embodiments of the present disclosure exhibit an average transmission of wavelengths between 400 nm and 700 nm through the article being reduced by less than 20%, 10%, 5%, or less than 1% after exposure to a certain dose of ultraviolet light (e.g., in units of Joules per square centimeter (J/cm²)). For instance, exposed to the doses mentioned in the Examples below.

### Microstructured Films

As mentioned above, a microstructured film comprises a first major surface and an opposing second major surface, wherein the first major surface comprises a plurality of microstructures projecting therefrom, wherein at least some of the plurality of microstructures each has a surface whose slope causes light that is normally incident to the first major surface of the microstructured film to intercept the first major surface or the surface of at least one other microstructure after reflection. As such, various different shapes of microstructures are suitable. For example, in some cases, the microstructures have a shape that is a prism, a pyramid, an inverted pyramid, a diffraction grating, an inverted cone, or a cone. Such shapes will be described in further detail below. Additionally, the inverse of any of these shapes are also suitable. Any number of facets of a three-dimensional shape may be present (e.g., any of a 4-sided pyramid, a 5-sided pyramid, a 6-sided pyramid, etc., would be suitable.). In select embodiments, each of the microstructures has the same size and shape, which tends to assist in achieving consistent optical performance of the multilayer optical film deposited on the microstructures across the surface of the structured ultraviolet light shielding article.

Optionally, at least some of the microstructures have a shape with a triangular cross-section, such as the microstructures 140 and 40 in FIGS. 1B and 1C, respectively. While not required, in some cases, at least some of the microstructures 140 comprise at least one angled sidewall (e.g., 142) that has a peak 145 that comes to a point. Advantageously, it was discovered that it is possible to form the multilayer optical film on microstructures that have peaks that come to a point (e.g., that are not rounded at the peak) without having “pinholes” due to inadequate deposition of the multilayer optical film on the points of the peaks.

In some cases, as depicted in FIG. 1B, at least some of the microstructures 140 comprise at least one angled sidewall (e.g., 142) having a peak angle (e.g., apex angle) theta (0) of 90 degrees or less, 85 degrees, 80 degrees, 75 degrees, 70 degrees, 65 degrees, 60 degrees, 55 degrees, 50 degrees, or 45 degrees or less; and 5 degrees or greater, 7 degrees, 10 degrees, 12 degrees, 15 degrees, 20 degrees, 25 degrees, 30 degrees, 35 degrees, 40 degrees, 45 degrees, or 50 degrees or greater. As used herein, the “peak angle” refers to the angle between opposing sides of a microstructure at the vertex of the microstructure.

Optionally, the plurality of microstructures 140 may have an aspect ratio of height H to (total) width W (i.e., H:W) of no more than 10:1, 9:1, 8:1, 7:1, 6:1, 5:1, 4:1, 3:1, 2:1, or no more than 1:1; and at least 1:2.

Typically, the microstructures each have a height of 0.5 micrometers or greater, 1 micrometer, 2 micrometers, 3 micrometers, 4 micrometers, 5 micrometers, 6 micrometers, 7 micrometers, 8 micrometers, 9 micrometers, 10 micrometers, 12 micrometers, 15 micrometers, 17 micrometers, 20 micrometers, 25 micrometers, 30 micrometers, 35 micrometers, 40 micrometers, 45 micrometers, 50 micrometers, 60 micrometers, 70 micrometers, 80 micrometers, 90 micrometers, 100 micrometers, 110 micrometers, 120 micrometers, 150 micrometers, 175 micrometers, 200 micrometers, 225 micrometers, or 250 micrometers or greater; and 500 micrometers or less, 475 micrometers, 450 micrometers, 425 micrometers, 400 micrometers, 375 micrometers, 350 micrometers, 325 micrometers, 300 micrometers, 275 micrometers, 250 micrometers, 225 micrometers, 200 micrometers, 175 micrometers, 150 micrometers, 125 micrometers, 100 micrometers, 75 micrometers, 50 micrometers, or 25 micrometers or less.

Referring to FIG. 3, in one embodiment, the first major surface 300 of a microstructured film 100 comprises a linear array of regular right prisms 320. Each prism has a first facet (e.g., sloped surface) 321 and a second facet 322. The prisms are illustrated as formed on a base member 310 that has a first planar surface 331 (parallel to reference plane 126) on which the prisms are formed and a second surface 332 that is substantially flat or planar and opposite first surface. It is envisioned that the second surface 332 could also be structured. By right prisms it is meant that the peak angle θ, 340, is typically about 90 degrees. However, this angle can range as described above. These peaks can be sharp (as shown) or rounded. The spacing between (e.g., prism) peaks may be characterized as pitch (“P”). In this embodiment, the pitch is also equal to the maximum width of the valley. The pitch may be greater than 1, 2, 3, 4, 5, 6, 7, 8, 9, or 10 microns (i.e., micrometers) ranging up to 250 microns. The length (“L”) of the (e.g., prism) microstructures is typically the largest dimension and can span the entire dimension of the microstructured surface.

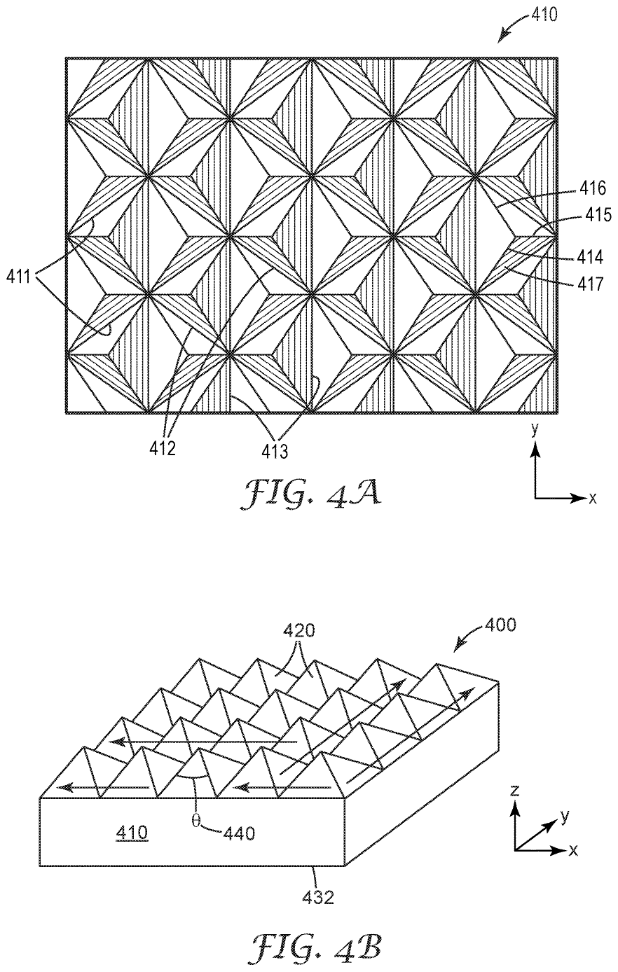

In another embodiment, the first major surface of the microstructured film may have the same surface shape as cube corner retroreflective sheeting. With reference to FIG. 4A, cube corner retroreflective sheeting typically comprises a thin transparent layer having a substantially planar surface and an opposing structured surface 410 comprising a plurality of cube corner elements 417. The microstructured surface 410 of FIG. 4A may be characterized as an array of cube corner elements 417 defined by three sets of parallel grooves (i.e., valleys) 411, 412, and 413; two sets of grooves (i.e., valleys) intersect each other at an angle greater than 60 degrees and a third set of grooves (valleys) intersects each of the other two sets at an angle less than 60 degrees to form an array of canted cube corner element matched pairs (see U.S. Pat. No. 4,588,258 (Hoopman)). The angles for the grooves are chosen such that the dihedral angle formed at the linear of intersection of the grooves, e.g., 414, 415, and 416 for representative cube-corner element 417 are about 90 degrees. In some embodiments, the triangular base has angle of at least 64, 65, 66, 67, 68, 69, or 70 degrees and the other angles are 55, 56, 57, or 58 degrees.

In another embodiment, depicted in FIG. 4B, the first major surface of the microstructured film 400 of FIG. 4B may be characterized as an array of pyramidal peak structures 420 defined by a first set of parallel grooves (i.e., valleys) in the y direction and a second set of parallel groves in the x direction. The base of the pyramidal peak structures is a polygon, typically a square or rectangle depending on the spacing of the grooves. The peak angle θ, 440, is typically about 90 degrees. However, this angle can range as described above.

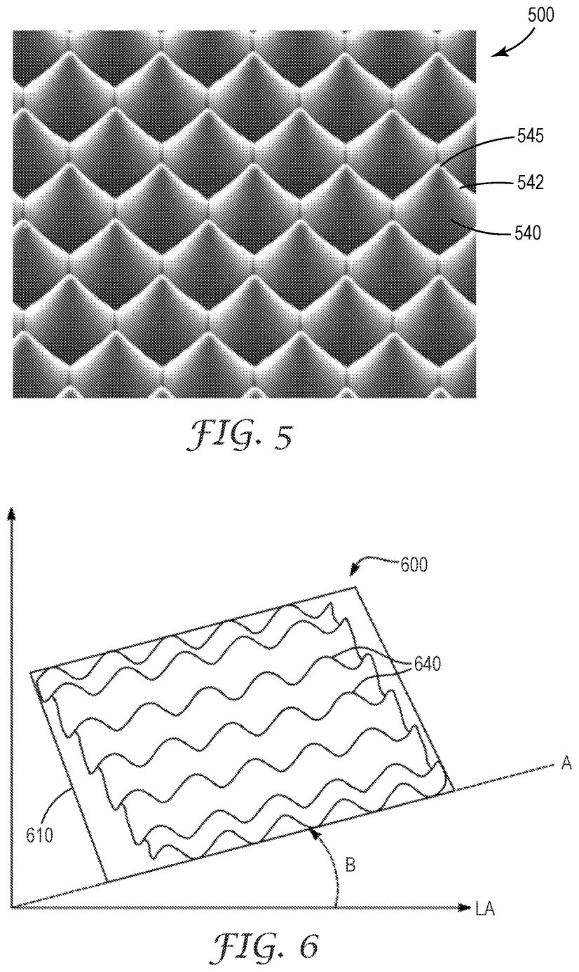

In some cases, the microstructures may have a shape of a cone. Referring to FIG. 5, a microstructured surface 500 of a microstructured film comprises an array of cones 540. Each microstructure of a cone shape typically has just one angled sidewall 542. The peak 545 of each cone can be pointed or rounded.

FIG. 6 depicts a schematic of a first major surface 600 of a microstructured film comprising a diffraction grating having a bias angle. A second major surface 610 of the microstructured film defines a longitudinal axis (“LA”) along its length and the plurality of microstructures 640 extends across the first major surface 600 to define a primary axis (“A”). The primary axis A and the longitudinal axis LA define a bias angle (“B”) therebetween. In some embodiments, the bias angle B is in a range of between about 0 degrees and about 90 degrees, such as between about 20 degrees and about 70 degrees.

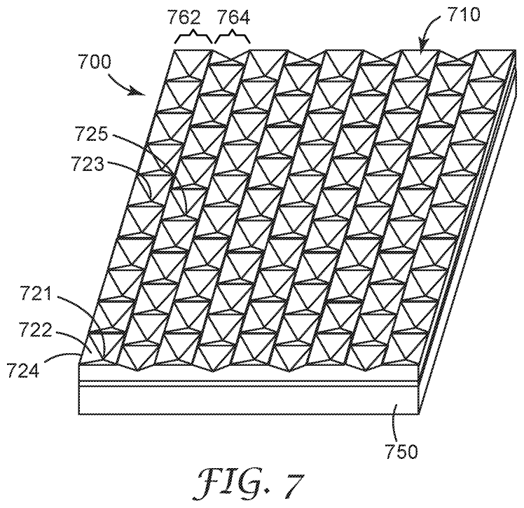

In another embodiment, depicted in FIG. 7, the first major surface 710 of the microstructured film 700 may be characterized as an array of inverted pyramid structures 720. The structures 720 include facets 722 that meet in a valley (e.g., inverted peak) 721, and the opposing edge 724 of each facet together form a base of the pyramid structure 720 (i.e., at the outermost surface of the microstructured film 700). The base of the pyramid is a polygon, such as a square or rectangle. In this particular embodiment, adjacent rows of structures (e.g., end row 762 is adjacent to row 764) are offset from each other such that the bottoms of the valleys of adjacent structures (e.g., 723 in row 762 and an adjacent structure 725 in row 764) have different positions along the length of the rows (e.g., in a y-axis). It is expressly contemplated that such an offset configuration may be employed with any of the microstructures disclosed herein.

In some cases, the microstructured film is flexible (as defined in the Glossary). An advantage to employing a flexible microstructured film is avoiding the high cost of working with rigid glass, particularly small pieces of glass, which can break during handling and require significant labor due to the need to apply many small pieces of glass. Additionally, in some embodiments according to the present disclosure flexible microstructured film are used in roll-to-roll processing of manufacturing the structured ultraviolet light shielding article. An advantage to roll-to-roll manufacturing is that the structured ultraviolet light shielding article can be made in large area form factors. In some cases, the microstructured film (or the structured ultraviolet light shielding article) has an area of at least 50 square centimeters, such as at least 60, 70, 80, 90, 100, 1,000, or at least 10,000 square centimeters.

In any of the foregoing embodiments, the microstructured film may be comprised of or consist of a polymeric material, such as a (co)polymer. In some exemplary embodiments, the microstructured film comprises polyethylene terephthalate (PET), a crosslinkable silicone, a cured polysiloxane, a silicone thermoplastic polymer, a cured urethane, a thermoplastic urethane, a cured (meth)acrylate, a cured epoxy, a cured vinyl ether, a cured oxetane, a cured thiol-acrylate, a cured thiol-ene, a polypropylene, a polyethylene, PMMA, coPMMA, a polyimide, a cyclic olefin copolymer, a cyclic olefin polymer, a polycarbonate, a polyethylene naphthalate (PEN), or a fluoropolymer (co)polymer comprising polymerized units derived from one or more monomers selected from tetrafluoroethylene, hexafluoropropylene, vinylidene fluoride, a perfluoroalkoxy alkylene, or a vinyl fluoride, or a combination thereof. Optionally, any of the cured polymeric materials mentioned above are crosslinked.

Suitable polyimides are available under the trade name “KAPTON” from E. I. DuPont de Nemours, Wilmington, DE, of which “KAPTON CS100” is currently preferred. Suitable PMMA polymers include those available as CP71 and CP80 from Ineos Acrylics, Inc., Wilmington, DE. One suitable crosslinkable silicone is available under the trade name “DOW CORNING 93-500 SPACE GRADE ENCAPSULANT KIT” from Dow Corning Corporation, Midland, MI. One suitable polycarbonate is available under the trade name “Makrofol”, from Bayer AG (Darmstadt, Germany). Suitable methyl methacrylate copolymers (CoPMMA) include, for instance, a CoPMMA made from 75 wt. % methylmethacrylate (MMA) monomers and 25 wt. % ethyl acrylate (EA) monomers, (available, for example, from Ineos Acrylics, Inc. (London, England) under the trade designation “PERSPEX CP63” or Arkema Corp., (Philadelphia, PA) under the trade designation “ATOGLAS 510”), a CoPMMA formed with MMA comonomer units and n-butyl methacrylate (nBMA) comonomer units, or a blend of PMMA and poly(vinylidene fluoride) (PVDF). Suitable polyethylene naphthalate (PEN) polymers are available under the tradename “Teonex Q51” from DuPont Teijin, Chester, VA.

In certain exemplary embodiments, the fluorinated (co)polymer preferably comprises tetrafluoroethylene, hexafluoropropylene, vinylidene fluoride, a perfluoroalkoxy alkane, or a combination thereof. Suitable fluoropolymers are available under the trade name “TEFLON FEP100” from E. I. DuPont de Nemours, Wilmington, DE, or which “TEFLON FEP100 500A is currently preferred. Suitable exemplary fluoropolymers also include copolymers of tetrafluorethylene, hexafluoropropylene, and vinylidene fluoride (THV) under the trade designations “DYNEON THV 220,” “DYNEON THV 221,” “DYNEON THV 230,” “DYNEON THV 2030,” “DYNEON THV 415”, “DYNEON THV 500”, “DYNEON THV 610”, and “DYNEON THV 815” from Dyneon LLC, Oakdale, MN.

In some applications, it may be useful to employ a low coefficient of thermal expansion (CTE) film, for instance when the article will be subjected to large variations in ambient temperature. Some exemplary low CTE polymers include for instance and without limitation, polyimide, heat stabilized PEN, and PET. Preferably, a low CTE material has a CTE of 80 parts per million per kelvin (ppm/K) or lower, 70 ppm/K, 60 ppm/K, 50 ppm/K, 40 ppm/K, 30 ppm/K, or even 25 ppm/K or less. The coefficient of thermal expansion has the general meaning as employed in the art, i.e., as determined using ASTM E831.

The smoothness and adhesion of layers to the microstructured film can be enhanced by appropriate optional pretreatment of the microstructured film or optional application of a priming layer. Methods for surface modification are known in the art. In one embodiment, a pretreatment regimen involves electrical discharge pretreatment of the substrate in the presence of a reactive or non-reactive atmosphere (e.g., plasma, glow discharge, corona discharge, dielectric barrier discharge or atmospheric pressure discharge), chemical pretreatment, or flame pretreatment. These pretreatments can help ensure that the surface of the microstructured film will be receptive to the subsequently applied layers. In one embodiment, the method can include plasma pretreatment. For organic surfaces, plasma pretreatments can include nitrogen or water vapor. Another pretreatment regimen involves coating the microstructured film with an inorganic or organic base coat layer optionally followed by further pretreatment using plasma or one of the other pretreatments described above.

Preferably, the microstructured film itself transmits an average of at least 70, 80, 90, or 95 percent of incident visible light in a wavelength range from greater than 400 nm to 700 nm.

### Optional Barrier Coating

In another embodiment, an optional barrier coating is disposed between the plurality of microstructures and the multilayer optical film. For instance, at the location of intermediate layer 14 in each of FIGS. 1C and 2. The barrier coating comprises: at least one dyad comprised of a (co)polymer layer overlaying the first major surface of the microstructured film and an inorganic layer overlaying the (co)polymer layer. The barrier coating further includes an outer (co)polymer layer overlaying the at least one dyad, and optionally, at least one outer inorganic layer overlaying the outer (co)polymer layer. As used in the context of the barrier coating, “outer” refers to being the outermost of a specific type of layer in the barrier coating (e.g., outer (co)polymer layer or outer inorganic layer), not an outermost layer of the structured ultraviolet light shielding article as a whole.

Structured ultraviolet light shielding articles that include a barrier coating provide protection from atomic oxygen environments. For instance, advantageously, in many cases the light shielding article exhibits an atomic oxygen degradation, when tested according to the Atomic Oxygen Degradation Test, of less than 1×10⁻²⁰ mg/atom, 1×10⁻²¹ mg/atom, or 1×10⁻²² mg/atom. Such resistance to degradation by atomic oxygen is particularly useful when the light shielding article is part of a low earth orbit device.

Barrier coatings of at least certain embodiments of the present disclosure can exhibit superior mechanical properties such as elasticity and flexibility yet still have low atomic oxygen degradation rates. The coatings have at least one dyad comprising a (co)polymer layer and an oxide layer and can have additional inorganic or hybrid organic/inorganic layers. In one embodiment, the barrier coatings can have alternating (co)polymer layers and oxide layers. In other exemplary embodiments, the disclosed barrier coatings can include one or more hybrid organic/inorganic layers. Optionally, the barrier coatings comprise a plurality of dyads, such as when the plurality of dyads is at least or exactly two dyads, three dyads, four dyads, five dyads, or six dyads.

Each (co)polymer layer in the at least one dyad and the outer (co)polymer layer comprises a (co)polymer selected from an olefinic (co)polymer, a (meth)acrylate (co)polymer, a urethane (co)polymer, a fluoropolymer, a silicone (co)polymer, or a combination thereof.

(Co)polymeric layers can be formed from a variety of organic materials or compounds using a variety of processes. The (co)polymeric layer may be crosslinked in situ after it is applied. In one embodiment, the (co)polymeric layer can be formed by flash evaporation, vapor deposition and (co)polymerization of a monomer using, for example, heat, plasma, UV radiation or an electron beam.

Exemplary monomers for use in such a method include volatilizable (meth)acrylate monomers. In a specific embodiment, volatilizable acrylate monomers are employed. Suitable (meth)acrylates will have a molecular weight that is sufficiently low to allow flash evaporation and sufficiently high to permit condensation on the substrate. The organic materials or compounds also can be vaporized using any methods like those described in PCT Publication No. WO 2022/243756 (Sweetnam et al.) for example the methods described with respect to vaporizing a metal alkoxide.

If desired, the (co)polymeric layers can alternatively be applied using conventional methods such as plasma deposition, solution coating, extrusion coating, roll coating (e.g., gravure roll coating), or spray coating (e.g., electrostatic spray coating), and if desired crosslinked or (co)polymerized, (e.g., as described above. The desired chemical composition and thickness of the additional layer will depend in part on the nature and desired purpose of the light shielding article. Coating efficiency can be improved by cooling the article.

Exemplary organic compounds include esters, vinyl compounds, alcohols, carboxylic acids, acid anhydrides, acyl halides, thiols, amines and mixtures thereof. Non-limiting examples of esters include (meth)acrylates, which can be used alone or in combination with other multifunctional or monofunctional (meth)acrylates. Exemplary (meth)acrylates include hexanediol diacrylate, ethoxyethyl acrylate, phenoxyethyl acrylate, cyanoethyl (mono)acrylate, isobornyl acrylate, octadecyl acrylate, isodecyl acrylate, lauryl acrylate, beta-carboxyethyl acrylate, tetrahydrofurfuryl acrylate, dinitrile acrylate, pentafluorophenyl acrylate, nitrophenyl acrylate, 2-phenoxyethyl acrylate, 2,2,2-trifluoromethyl acrylate, diethylene glycol diacrylate, triethylene glycol diacrylate, tripropylene glycol diacrylate, tetraethylene glycol diacrylate, neopentyl glycol diacrylate, propoxylated neopentyl glycol diacrylate, polyethylene glycol diacrylate, tetraethylene glycol diacrylate, bisphenol A epoxy diacrylate, trimethylol propane triacrylate, ethoxylated trimethylol propane triacrylate, propylated trimethylol propane triacrylate, tris(2-hydroxyethyl)-isocyanurate triacrylate, pentaerythritol triacrylate, phenylthioethyl acrylate, naphthloxyethyl acrylate, IRR-214 cyclic diacrylate from UCB Chemicals, epoxy acrylate RDX80095 from Rad-Cure Corporation, the corresponding methacrylates of the acrylates listed above and mixtures thereof. Exemplary vinyl compounds include vinyl ethers, styrene, vinyl naphthylene and acrylonitrile. Exemplary alcohols include hexanediol, naphthalenediol and hydroxyethylmethacrylate. Exemplary carboxylic acids include phthalic acid and terephthalic acid, (meth)acrylic acid). Exemplary acid anhydrides include phthalic anhydride and glutaric anhydride. Exemplary acyl halides include hexanedioyl dichloride, and succinyl dichloride. Exemplary thiols include ethyleneglycol-bisthioglycolate, and phenylthioethylacrylate. Exemplary amines include ethylene diamine and hexane 1,6-diamine.

Optionally, at least one (co)polymer layer in the at least one dyad or the outer (co)polymer layer further comprises an additive that is an ultraviolet radiation absorber, a hindered amine light stabilizer, an antioxidant, or a combination thereof. UV absorbers (UVAs), Hindered Amine Light Stabilizers (HALs), and antioxidants can help prevention of photo-oxidation degradation of the (co)polymer layer. Suitable compounds include benzophenones, benzotriazoles, and triazines (e.g., benzotriazines). Exemplary UVAs for incorporation into the (co)polymer layer include those available under the trade designations “TINUVIN 1577” and “TINUVIN 1600,” from BASF Corporation, Florham Park, NJ. U.S. Pat. No. 9,670,300 (Olson et al.) and U.S. Pat. App. Pub. No. 2017/0198129 (Olson et al.) describe exemplary UVA oligomers that are compatible with PVDF fluoropolymers. Exemplary HALs for incorporation into the hard coat layer include those available under the trade designations “CHIMMASORB 944” and “TINUVIN 123,” from BASF Corporation. Typically, UVAs, HALs, and/or antioxidants are incorporated in the (co)polymer layer at a concentration of 1-10 wt. %.

Each of the inorganic layers in the at least one dyad and the optional at least one outer inorganic layer overlaying the outer (co)polymer layer comprises an inorganic material selected from silicon oxide, silica alumina oxide, silicon oxynitride, gallium oxide, magnesium oxide, niobium oxide, titanium dioxide, yttrium oxide, zinc oxide, tin oxide, nickel oxide, tungsten oxide, aluminum doped zinc oxide, indium tin oxide, zirconium oxide, zirconium oxynitride, hafnia, aluminum oxide, alumina doped silicon oxide, lanthanum fluoride, neodymium fluoride, aluminum fluoride, magnesium fluoride, calcium fluoride, or a combination thereof.

An outer (co)polymer layer overlays the at least one dyad, which may be a plurality of dyads as mentioned above. The outer (co)polymer layer is preferably crosslinked.

In some exemplary embodiments, the outer (co)polymer layer comprises an olefinic (co)polymer selected from low density polyethylene, linear low density polyethylene, ethylene vinyl acetate, polyethylene methyl acrylate, polyethylene octene, polyethylene propylene, polyethylene butene, polyethylene maleic anhydride, polymethyl pentene, polyisobutene, polyisobutylene, polyethylene propylene diene, cyclic olefin (co)polymers, and blends thereof.

In certain exemplary embodiments, the at least one (co)polymer layer in the at least one dyad or the outer (co)polymer layer further comprises an ultraviolet radiation absorber, a hindered amine light stabilizer, an antioxidant, or a combination thereof.

The ultraviolet radiation absorber is preferably selected from a benzotriazole compound, a benzophenone compound, a triazine compound, or a combination thereof. Presently preferred hindered amine light stabilizers are available from BASF U.S.A (Florham Park, NJ) under the trade name “TINUVIN”. The hindered amine light stabilizer is preferably selected from TINUVIN 123, TINUVIN 144, TINUVIN 292, or a combination thereof. Presently preferred anti-oxidants are available from BASF under the trade name “IRGANOX” and “IRGAFOS”. Suitable antioxidants for polyolefins are preferably selected from IRGANOX 1010, IRGANOX 1076, IRGAFOS 168, or a combination thereof.

The barrier coatings can be subjected to various post-treatments such as heat treatment, UV or vacuum UV (VUV) treatment, or plasma treatment. Heat treatment can be conducted by passing the barrier coating through an oven or directly heating the barrier coating in the coating apparatus, (e.g., using infrared heaters or heating directly on a drum. Heat treatment may for example be performed at temperatures from about 30° C. to about 200° C., about 35° C. to about 150° C., or about 40° C. to about 70° C.

### Optional Organic Base Coat Layer

In another embodiment, optional organic base coat layers, and especially base coat layers based on crosslinked acrylate (co)polymers, may be advantageously employed on the microstructured film. The base coat layer can be formed by flash evaporation and vapor deposition of a radiation-crosslinkable monomer (e.g., an acrylate monomer), followed by crosslinking in situ (using, for example, an electron beam apparatus, UV light source, electrical discharge apparatus or other suitable device), as described in U.S. Pat. Nos. 4,696,719, 4,722,515, 4,842,893, 4,954,371, 5,018,048, 5,032,461, 5,097,800, 5,125,138, 5,440,446, 5,547,908, 6,045,864, 6,231,939 and 6,214,422; in published PCT Application No. WO 00/26973; in D. G. Shaw and M. G. Langlois, “A New Vapor Deposition Process for Coating Paper and (co)polymer Webs”, 6th International Vacuum Coating Conference (1992); in D. G. Shaw and M. G. Langlois, “A New High Speed Process for Vapor Depositing Acrylate Thin Films: An Update”, Society of Vacuum Coaters 36th Annual Technical Conference Proceedings (1993); in D. G. Shaw and M. G. Langlois, “Use of Vapor Deposited Acrylate Coatings to Improve the Barrier Properties of Metallized Film”, Society of Vacuum Coaters 37th Annual Technical Conference Proceedings (1994); in D. G. Shaw, M. Roehrig, M. G. Langlois and C. Sheehan, “Use of Evaporated Acrylate Coatings to Smooth the Surface of Polyester and Polypropylene Film Substrates”, RadTech (1996); in J. Affinito, P. Martin, M. Gross, C. Coronado and E. Greenwell, “Vacuum deposited (co)polymer/metal multilayer films for optical application”, Thin Solid Films 270, 43-48 (1995); and in J. D. Affinito, M. E. Gross, C. A. Coronado, G. L. Graff, E. N. Greenwell and P. M. Martin, “(co)polymer-Oxide Transparent Barrier Layers”, Society of Vacuum Coaters 39th Annual Technical Conference Proceedings (1996).

If desired, the base coat can also be applied using conventional coating methods such as roll coating (e.g., gravure roll coating) or spray coating (e.g., electrostatic spray coating), then crosslinked using, for example, heat, UV radiation or an electron beam. The desired chemical composition and thickness of the base coat layer will depend in part on the nature of the microstructured film. For example, for PET, the base coat layer can be formed from an acrylate monomer and may for example have a thickness of only a few nm up to about 7 micrometers.

### Multilayer Optical Films

Referring again to FIG. 2, the structured ultraviolet light shielding article 10 includes a multilayer optical film 20 comprising one or more alternating first inorganic optical layers 13 (A-N) and second inorganic optical layers 12 (A-N) positioned on the first major surface 5 of the microstructured film 15 as described further below.

Typically, the multilayer optical film has a thickness of 200 nm or greater, 250 nm, 300 nm, 350 nm, 400 nm, 500 nm, or 550 nm or greater; and 1500 nm or less, 1400 nm, 1300 nm, 1200 nm, 1100 nm, 1000 nm, 900 nm, 850 nm. 800 nm, 750 nm, 700 nm, 650 nm, or 600 nm or less, such as a thickness of 200 nm to 1500 nm.

### Inorganic Layers

In some cases, the first optical layer comprises at least one of niobium oxide, titanium oxide, silicon oxynitride, molybdenum oxide, tungsten oxide, silicon nitride, indium tin oxide, hafnium oxide, tantalum oxide, zirconium oxynitride, zirconium oxide, aluminum zinc oxide, or zinc oxide. Alloys of oxides may be suitable, as known to those skilled in the art. In some cases, the second optical layer comprises at least one of silicon oxide, silicon aluminum oxide, N type- or P type-doped silicon oxide, aluminum oxide, aluminum fluoride, magnesium fluoride, calcium fluoride, indium tin oxide, or zinc oxide. In select embodiments, the first optical layer comprises at least one of niobium oxide or titanium oxide, and the second optical layer comprises silicon aluminum oxide. When a photoactive inorganic material such as titanium oxide is employed, typically a non-photoactive material (e.g., silicon oxide, aluminum oxide, etc.) may be disposed between the photoactive inorganic material and any organic layers to minimize degradation of the organic layer. For instance, referring again to FIG. 2, a layer of a non-photoactive material could be an intermediate layer 14 located between the first optical layer 13N and the microstructured film 15.

It was unexpectedly discovered that wavelengths of light in each of UVA, UVB, and UVC regions could be shielded from a microstructured film using just the combined reflectance and absorbance of a plurality of alternating first inorganic optical layers and second inorganic optical layers, typically while still maintaining an acceptable amount of transmission of visible light (e.g., at least 50% of incident visible light).

Optical thin film stack designs comprised of alternating thin layers of inorganic dielectric materials with refractive index contrast, are particularly suited for the multilayer optical film. In recent decades they have been used for applications in UV, Visible, NIR and IR spectral regions. Depending upon the spectral region of interest, there are specific materials suitable for that region. Also, for coating these materials, one of two forms of physical vapor deposition (PVD) are used: evaporation or sputtering. Evaporated coatings rely upon heating the coating material (evaporant) to a temperature at which it evaporates. This is followed by condensation of the vapor upon a substrate. For evaporated dielectric mirror coatings, the electron-beam deposition process is most commonly used. Sputtered coatings use energetic gas ions to bombard a material (“target”) surface, ejecting atoms which then condense on the nearby substrate. Depending upon which coating method is used, and the settings used for that method, thin film coating rate and structure-property relationships will be strongly influenced. Ideally, coating rates should be high enough to allow acceptable process throughput and film performance, characterized as dense, low stress, void free, non-optically absorbing coated layers.

The number of optical layers is selected to achieve the desired optical properties using the minimum number of layers for reasons of film thickness, flexibility and economy. One skilled in the art could extend such deposition techniques to include CVD, ALD, and other vapor depositions. Typically, the total number of layers is preferably 21 or less, 19, 17, 15, or 13 optical layers or less; and 3 optical layers or more, 5, 7, 9, or 11 optical layers or more, may be needed. In select embodiments, the multilayer optical film is formed of at least 1 first optical layer and 2 second optical layers.

The thickness of each of the first and second optical layers can vary substantially. For instance, in some cases each of the first optical layers and each of the second optical layers independently has a thickness of 5 nm or greater, 10 nm, 15 nm, 20 nm, 25 nm, 30 nm, 35 nm, 40 nm, 45 nm, 50 nm, 55 nm, 60 nm, 65 nm, or 70 nm or greater; and a thickness of 2000 nm or less, 500 nm, 145 nm, 140 nm, 135 nm, 130 nm, 125 nm, 120 nm, 115 nm, 110 nm, 105 nm, 100 nm, 95 nm, 90 nm, 85 nm, 80 nm, or 75 nm or less. In select embodiments, each of the first and second optical layers independently has a thickness of 20 nm to 400 nm.

Multilayer optical films described herein can be made using general processing techniques, such as those described in U.S. Pat. No. 6,783,349 (Neavin et al.), the entire disclosure of which is incorporated herein by reference in its entirety.

For manufacturing inorganic coatings, the electron beam process is best suited for coating discrete parts. Optionally, ultraviolet light shielding articles can be prepared in continuous roll-to-roll (R2R) fashion for larger articles. Though some chambers have demonstrated R2R film coating, the layer by layer coating sequence would still be necessary. For R2R sputtering of inorganic layers of ultraviolet light shielding articles 10, it is advantageous to use a sputtering system with multiple sources located around one, or perhaps two, coating drums. Here, for a thirteen layers optical stack design, a two, or even single, machine pass process, with alternating high and low refractive index layers coated sequentially, would be feasible. How many machine passes needed would be contingent upon machine design, cost, practicality of thirteen consecutive sources, and the like. Additionally, coating rates would need to be matched to a single film line speed.

The film roll transport initially starts at a pre-determined speed, and the sputter source power is ramped to full operating power, followed by introduction of the reactive gases and then achieving steady state condition. Depending upon the length of film to coat, the process continues until total footage is achieved. Here, as the sputter source is orthogonal to and wider than the film which is being coated, the uniformity of coating thickness is quite high. Upon reaching the desired length of coated film the reactive gases are set to zero and the target is sputtered to a pure metal surface state. The film direction is next reversed and a rotary pair of sputter targets has AC frequency (40 kHz) power applied in an argon sputtering atmosphere. Upon reaching steady state, oxygen reactive gas is introduced to provide transparency and low refractive index. At the pre-determined process setting and line speed the second layer is coated over the length which was coated for layer one. Again, as these sputter sources are also orthogonal to and wider than the film being coated, the uniformity of coating thickness is quite high. After reaching the desired length of coated film the reactive oxygen is removed and the target is sputtered in argon to a pure metal surface state. Layers three to five (or seven or nine, eleven or thirteen, etc.) depending upon optical targets, are coated in this sequence. Upon completion, the film roll is removed for post-processing.

The Examples describe in more detail exemplary processes to make exemplary structured ultraviolet light shielding articles 10.

### Solar Arrays

In a second aspect, a solar array is provided. The solar array includes a structured ultraviolet light shielding article according to any embodiments of the first aspect described in detail above.

One of the promising energy resources today is sunlight. Harnessing sunlight may be accomplished by the use of photovoltaic (PV) cells (also referred to as solar cells), which are used for photovoltaic conversion of sunlight to electrical current. Solar cells are relatively small in size and typically combined into a physically integrated solar module (or PV module) having a correspondingly greater power output than the individual solar cells of the module. Solar modules are generally formed from two or more “strings” of solar cells surrounded by an encapsulant and enclosed by front and back panels, wherein at least one panel is transparent to sunlight.

Ultraviolet shielding articles according to the present disclosure may thus be used to protect an array of solar cells by being included on an exterior surface of the solar array.

Referring again to FIG. 2, the present disclosure describes solar arrays 30 each including a structured ultraviolet light shielding article 10 positioned on an exterior surface 16 of a solar cell array. In some cases, the structured ultraviolet light shielding article 10 may be directly attached to the surface of the solar array 16, e.g., by using heat lamination. There may instead be one or more optional intermediate layers (not shown) between the structured ultraviolet light shielding article 10 and the solar array surface 16, such as a transparent adhesive tie layer or an encapsulant. The structure ultraviolet light shielding article 10 includes a microstructured film 15 having a first major surface 5 and a multilayer optical film 20 positioned on the first major surface 5 of the microstructured film 15.

### Listing of Exemplary Embodiments

In a first embodiment is provided a structured ultraviolet light shielding article. The ultraviolet light shielding article comprises a) a microstructured film comprising a first major surface and an opposing second major surface, wherein the first major surface comprises a plurality of microstructures projecting therefrom; and b) a multilayer optical film disposed on the plurality of microstructures. At least some of the plurality of microstructures each has a surface whose slope causes light that is normally incident to the first major surface of the microstructured film to intercept the first major surface or the surface of at least one other microstructure after reflection. The multilayer optical film is comprised of one or more alternating first and second inorganic optical layers collectively reflecting and absorbing light that is normally incident to the first major surface of the microstructured film, an average of at least 50, 60, 70, 80, 90, or 95 percent of incident ultraviolet light over at least a 30-nanometer wavelength reflection bandwidth in a wavelength range from 190 nanometers (nm) to 400 nm.

In a second embodiment is provided a structured ultraviolet light shielding article according to the first embodiment, wherein the plurality of microstructures have an aspect ratio of height to width of no more than 10:1, 8:1, 6:1, 4:1, 2:1, or 1:1.

In a third embodiment is provided a structured ultraviolet light shielding article according to the first embodiment or the second embodiment, wherein the microstructured film comprises a polyethylene, polyethylene terephthalate (PET), a crosslinkable silicone, a silicone thermoplastic polymer, a cured urethane, a thermoplastic urethane, a cured (meth)acrylate, a cured epoxy, a cured vinyl ether, a cured oxetane, a cured thiol-acrylate, a cured thiol-ene, a polypropylene, a polyethylene, PMMA, coPMMA, a polyimide, a cyclic olefin copolymer, a cyclic olefin polymer, a polycarbonate, PEN, or a fluoropolymer (co)polymer comprising polymerized units derived from one or more monomers selected from tetrafluoroethylene, hexafluoropropylene, vinylidene fluoride, a perfluoroalkoxy alkylene, or a vinyl fluoride, or a combination thereof.

In a fourth embodiment is provided a structured ultraviolet light shielding article according to any of the first through third embodiments, wherein at least some of the microstructures comprise at least one angled sidewall that has a peak that comes to a point.

In a fifth embodiment is provided a structured ultraviolet light shielding article according to any of the first through fourth embodiments, wherein at least some of the microstructures comprise at least one angled sidewall having a peak angle of 90 degrees or less.

In a sixth embodiment is provided a structured ultraviolet light shielding article according to any of the first through fifth embodiments, wherein at least some of the microstructures have a shape with a triangular cross-section.

In a seventh embodiment is provided a structured ultraviolet light shielding article according to any of the first through sixth embodiments, wherein the microstructures have a shape that is a prism, a pyramid, an inverted pyramid, a diffraction grating, an inverted cone, or a cone.

In an eighth embodiment is provided a structured ultraviolet light shielding article according to any of the first through seventh embodiments, wherein each of the microstructures has the same size and shape.

In a ninth embodiment is provided a structured ultraviolet light shielding article according to any of the first through eighth embodiments, wherein the microstructured film is flexible.

In a tenth embodiment is provided a structured ultraviolet light shielding article according to any of the first through ninth embodiments, wherein the microstructures have a height of 0.5 micrometer to 500 micrometers.

In an eleventh embodiment is provided a structured ultraviolet light shielding article according to any of the first through tenth embodiments, wherein the peak angle is 5, 15, 25, 35, or 45 degrees or greater.

In a twelfth embodiment is provided a structured ultraviolet light shielding article according to any of the first through eleventh embodiments, wherein each of the first and second optical layers independently has a thickness of 20 nm to 400 nm.

In a thirteenth embodiment is provided a structured ultraviolet light shielding article according to any of the first through twelfth embodiments, wherein the alternating first and second inorganic optical layers collectively absorb light that is normally incident to the first major surface of the microstructured film, an average of at least 30, 40, 50, 60, 70, 80, 90, or 95 percent of incident light over at least a 30-nanometer wavelength bandwidth in a wavelength range from 190 nm to less than 350 nm.

In a fourteenth embodiment is provided a structured ultraviolet light shielding article according to any of the first through thirteenth embodiments, wherein the alternating first and second inorganic optical layers collectively reflect light that is normally incident to the first major surface of the microstructured film, an average of at least 30, 40, 50, 60, 70, 80, 90, or 95 percent of incident light over at least a 30-nanometer wavelength bandwidth in a wavelength range from 190 nm to less than 400 nm, 190 nm to 240 nm, 240 nm to 300 nm, 300 nm to 350 nm, 350 nm to less than 400 nm, or any combination thereof.

In a fifteenth embodiment is provided a structured ultraviolet light shielding article according to any of the first through fourteenth embodiments, wherein the alternating first and second inorganic optical layers collectively transmit light that is normally incident to the first major surface of the microstructured film, an average of at least 50, 60, 70, 80, 90, or 95 percent of incident visible light in a wavelength range from greater than 400 nm to 700 nm.

In a sixteenth embodiment is provided a structured ultraviolet light shielding article according to any of the first through fifteenth embodiments, wherein the microstructured film transmits an average of at least 70, 80, 90, or 95 percent of incident visible light in a wavelength range from greater than 400 nm to 700 nm.

In a seventeenth embodiment is provided a structured ultraviolet light shielding article according to any of the first through sixteenth embodiments, wherein the first optical layer comprises at least one of niobium oxide, titanium oxide, silicon oxynitride, molybdenum oxide, tungsten oxide, silicon nitride, indium tin oxide, hafnium oxide, tantalum oxide, zirconium oxynitride, zirconium oxide, aluminum zinc oxide, or zinc oxide and wherein the second optical layer comprises at least one of silicon oxide, silicon aluminum oxide, N type- or P type-doped silicon oxide, aluminum oxide, aluminum fluoride, magnesium fluoride, calcium fluoride, indium tin oxide, or zinc oxide.

In an eighteenth embodiment is provided a structured ultraviolet light shielding article according to any of the first through seventeenth embodiments, wherein the first optical layer comprises at least one of niobium oxide or titanium oxide, and wherein the second optical layer comprises silicon aluminum oxide.

In a nineteenth embodiment is provided a structured ultraviolet light shielding article according to any of the first through eighteenth embodiments, wherein the outermost optical layer is a second optical layer and has a thickness of at least 70 nm.

In a twentieth embodiment is provided a structured ultraviolet light shielding article according to any of the first through nineteenth embodiments, wherein at least one of the first optical layers nearest to the exterior of the film or nearest to the microstructures has a thickness of at most 95%, 90%, 85%, or at most 80% of the other first optical layers.

In a twenty-first embodiment is provided a structured ultraviolet light shielding article according to any of the first through twentieth embodiments, wherein the multilayer optical film has a thickness of 200 nm to 1500 nm.

In a twenty-second embodiment is provided a structured ultraviolet light shielding article according to any of the first through twenty-first embodiments, wherein the multilayer optical film is formed of at least 1 first optical layer and 2 second optical layers.

In a twenty-third embodiment is provided a structured ultraviolet light shielding article according to any of the first through twenty-second embodiments, wherein the alternating first and second inorganic optical layers collectively reflect and absorb light that is normally incident to the first major surface of the microstructured film, an average of at least 80, 90, or 95 percent of incident ultraviolet light over at least a 30-nanometer wavelength reflection bandwidth in a wavelength range from 190 nm to 400 nm.

In a twenty-fourth embodiment is provided a structured ultraviolet light shielding article according to any of the first through twenty-third embodiments, wherein the alternating first and second inorganic optical layers collectively reflect and absorb light that is normally incident to the first major surface of the microstructured film, an average of at least 60, 70, 80, 90, or 95 percent of incident ultraviolet light over at least a 30-nanometer wavelength reflection bandwidth in a wavelength range from 190 nm to 240 nm, 240 nm to 300 nm, 300 nm to 350 nm, 350 nm to 400 nm, or any combination thereof.

In a twenty-fifth embodiment is provided a structured ultraviolet light shielding article according to any of the first through twenty-fourth embodiments, wherein the alternating first and second inorganic optical layers collectively reflect and absorb light that is normally incident to the first major surface of the microstructured film, an average of at least 60, 70, 80, 90, or 95 percent of incident ultraviolet light over at least a 50-nanometer, 75-nanometer, 100-nanometer, 125-nanometer, 150-nanometer, or 175-nanometer wavelength reflection bandwidth in a wavelength range from 190 nm to 400 nm.

In a twenty-sixth embodiment is provided a structured ultraviolet light shielding article according to any of the first through twenty-fifth embodiments, which transmits light that is normally incident to the first major surface of the microstructured film, an average of at least 50, 60, 70, 80, 90, or 95 percent of incident visible light in a wavelength range from greater than 400 nm to 700 nm.

In a twenty-seventh embodiment is provided a structured ultraviolet light shielding article according to any of the first through twenty-sixth embodiments, further comprising a barrier coating disposed between the plurality of microstructures and the multilayer optical film, the barrier coating comprising: at least one dyad comprised of a (co)polymer layer overlaying the first major surface of the microstructured film and an inorganic layer overlaying the (co)polymer layer; and an outer (co)polymer layer overlaying the at least one dyad; and optionally, at least one outer inorganic layer overlaying the outer (co)polymer layer.

In a twenty-eighth embodiment is provided a structured ultraviolet light shielding article according to any of the first through twenty-seventh embodiments, exhibiting an average transmission of wavelengths between 400 nm and 700 nm through the article that is reduced by less than 20%, 10%, 5%, or less than 1% after exposure to a certain dose of ultraviolet light.

In a twenty-ninth embodiment is provided a solar array. The solar array comprises a structured ultraviolet light shielding article according to any of the first through twenty-eighth embodiments disposed on an exterior surface of the solar array.

### Examples

Unless otherwise noted or readily apparent from the context, all parts, percentages, ratios, etc. in the Examples and the rest of the specification are by weight.

### Materials Used in the Examples

| Abbreviation | Description and Source |
|---|---|
| BEF4 | A microstructured film with 1-dimensional prisms, peak angle of 90 |
| | degrees, and pitch of 24 um, obtained under tradename “3M ™ Brightness |
| | Enhancement Films BEF4-GT” from 3M; St. Paul, MN |
| TiO₂ | TiO₂ source material was purchased under trade name “Titanium Oxide |
| | tablets, TiO₂, 99.9% pure” from Kurt J Lesker Company; Jefferson Hills, |
| | PA. |
| SiO₂ | SiO₂ source material was purchased under trade name “Silicon Oxide |
| | Pieces, SiO₂, 99.99% pure” from Kurt J Lesker Company; Jefferson |
| | Hills, PA. |
| Silicon chip | Silicon wafers cut into 0.75″ × 0.75″ pieces, obtained under part number |
| | “452” from University Wafer Inc; South Boston, MA |

### Test Methods

Spectral Properties Modeling Test: Prior to fabricating the structured ultraviolet light shielding articles, we modeled the optical properties (transmission, reflection, and absorption) of the intended coating to precisely determine the necessary thicknesses of the optical coating layers. To perform this modeling, Test Samples 1 and 2 were measured with an ellipsometer (obtained under tradename “RC2 Ellipsometer” from J. A. Woolam; Lincoln, NE) to determine the spectral index of refraction (n) and extinction coefficient (k) values of the evaporated TiO₂ and SiO₂ samples. Then the n and k obtained above were input into optical modeling software (obtained under tradename “Essential MaCleod” from The Thin Film Center; Tucson, AZ) and used to compute the reflection, transmission, and absorption spectra for the multilayer optical films prepared as described below. All structures were modeled with a PET substrate, with an incident angle of 45 degrees.

### Test Samples

Test Sample 1: A 70 nm-thick TiO₂ layer was deposited on a silicon chip in the following manner: the vapor coater used was a Denton Vacuum Optical Coater consisting of a 5-planet planetary drive system located ˜30″ (76.2 cm) above a 4-pocket Temescal Electron Beam gun (obtained from Ferro Tec Corporation, Livermore, CA). The planetary was designed to hold the substrate perpendicular to the evaporation source and to move that disk in a planetary type motion in and out of the evaporation plume during the deposition. The actual process for the coating consisted of: a) The vapor coater was vented to atmosphere and one the five planets was removed. We prepared the substrate for coating by adhering/taping it to the planet by a polyimide tape. b) The planet was reinstalled, and the other 4 planets were configured similarly, if needed, and they too were reinstalled in the coater. c) The chamber was closed and pumped to a vacuum level of <2×10⁻⁵ Torr (2.7×10⁻³ Pa). d) When the vapor coater was at a low enough vacuum, we ion beam treated the material using a Kaufman-type ion source for ˜10 minutes at a voltage of 400V as a pretreatment to the substrate for adhesion of the vapor deposited coating to the substrate prior to applying the oxide films. e) We added oxygen gas via a MKS mass flow controller (obtained from MKS Instruments, Inc., Andover, MA) to obtain a pressure of 4.0×10⁻⁵ Torr (5.3×10⁻³ Pa). This was usually about 10 standard cubic centimeters per minute (seems) for added oxygen gas. f) The planetary was started and moved around the coater at a rotational speed of ˜60 rpm to prepare for coating and to achieve a high level of uniformity on the attached substrates. g) A Temescal electron beam gun power supply was energized. A voltage of 10 kV and a current of a few milliamps was applied to the e-gun's filament, heating the source material in the e-gun. The source was heated and controlled via an Eddy Company Optical Monitoring System (OMS) (from Eddy Company, Apple Valley, CA). The source was heated until the desired deposition rate of the material was achieved; in the case of TiO₂ this rate was 2 angstroms per second (A/s), and in the case of SiO₂ this was 4 A/s. When the desired deposition rate of the material was achieved and steady, a shutter that separates the source from the planets was opened and the rate was maintained via the OMS until the desired optical thickness was achieved, at which point the shutter closed and the OMS shuts power off to the e-beam source. h) The main power to the power supply was turned off and the source allowed to cool for about 10 minutes. i) This process was repeated for additional layers/types of material until the full desired multilayer optical film had been deposited. j) The chamber was then vented back to atmospheric pressure via N₂ gas and each planet was removed and the substrate was removed from each planet.

Test Sample 2: a 115 nm-thick SiO₂ layer was deposited on a silicon chip in the same manner as Test Sample 1.

### Examples

Unless otherwise noted or readily apparent from the context, all parts, percentages, ratios, etc. in the Examples and the rest of the specification are by weight.

| Abbreviation | Description and Source |
|---|---|
| BEF4 | A microstructured film with 1-dimensional prisms, peak angle of |
| | 90 degrees, and pitch of 24 um, obtained under tradename “3M ™ |
| | Brightness Enhancement Films BEF4-GT” from 3M; St. Paul, |
| | MN |
| TiO₂ | TiO₂ source material was purchased under trade name “Titanium |
| | Oxide tablets, TiO₂, 99.9% pure” from Kurt J Lesker Company; |
| | Jefferson Hills, PA. |
| SiO₂ | SiO₂ source material was purchased under trade name “Silicon |
| | Oxide Pieces, SiO₂, 99.99% pure” from Kurt J Lesker Company; |
| | Jefferson Hills, PA. |
| 90% Si/10% Al sputtering | 90% Si/10% Al sputtering targets obtained from Soleras |
| targets | Advanced Coatings US, of Biddeford, Me. |
| Silicon chip | Silicon wafers cut into 0.75″ × 0.75″ pieces, obtained under part |
| | number “452” from University Wafer Inc; South Boston, MA |
| BK7 | 21.57 mm by 21.57 mm by 1.5 mm BK7 glass, obtained under |
| | tradename “BK7 Chips” from Eddy Company; Apple Valley, CA |
| SR833S | Tricyclodecane dimethanol diacrylate monomer, obtained under |
| | the trade designation “SR833S” from Sartomer USA, Exton, PA. |
| THV815 | Fluoropolymer resin available obtained under the tradename |
| | “3M ™ Dyneon ™ Fluoroplastic Granules THV 815GZ” from 3M; |
| | St. Paul, MN |
| DYNASYLAN 1189 | N-(n-butyl)-3-aminopropyltrimethoxysilane obtained as |
| | DYNASYLAN 1189 from Evonik of Essen, Del. |

### Materials Used in the Examples

### Test Methods

Spectral Properties Modeling Test: Prior to fabricating the structured ultraviolet light shielding articles, we modeled the optical properties (transmission, reflection, and absorption) of the intended coating to precisely determine the necessary thicknesses of the optical coating layers. To perform this modeling, Test Samples 1 and 2 were measured with an ellipsometer (obtained under tradename “RC2 Ellipsometer” from J. A. Woolam; Lincoln, NE) to determine the spectral index of refraction (n) and extinction coefficient (k) values of the evaporated TiO₂ and SiO₂ samples. Then the n and k obtained above were input into optical modeling software (obtained under tradename “Essential MaCleod” from The Thin Film Center; Tucson, AZ) and used to compute the reflection, transmission, and absorption spectra for the multilayer optical films prepared as described below. All structures were modeled with a PET substrate, with an incident angle of 45 degrees except comparative Example 1 which was modeled with normally incident light.

Spectral Properties Measurement Test: The spectral transmission and reflection of freestanding examples of ultraviolet light shielding articles were measured using a spectrophotometer (obtained under the trade designation “LAMBDA 1050” from PerkinElmer, Inc., Waltham, MA). Absorption was calculated (in units of percentage) as 100—Reflection—Transmission. The measured spectral reflection, absorption, and transmission are reported as an average percent over a wavelength range in the Reflection and Absorption Results Table and Transmission Results Table.

Solar Aging Test: Samples were exposed in an Atlas Ci5000 Weather-Ometer (obtained from AMETEK, Berwyn, PA) using a xenon arc lamp equipped with quartz inner and outer filters. The quartz filter set provides minimal attenuation to the spectral power distribution of the xenon lamp, which gives a close approximation to the shape of solar output (ASTM E490). To increase the rate at which dosage is accumulated, the samples were exposed on custom-made stainless steel and aluminum extended holders. The extended holders move the exposure plane from 19 inches (48.3 cm) away from the core of the lamp to 13.5 inches (34.3 cm) from the core of the lamp. Irradiance was controlled at 1.5 W/m² at 340 nm at the rack plane and was measured to be 2.6 W/m² at 340 nm at the extended sample plane. Ambient air temperature inside the Weatherometer was controlled at 48° C., a black-panel thermometer (BPT) was controlled at 75° C. at the rack plane and measured to be approximately 95° C. at the sample plane, and relative humidity was controlled at 30%. Samples were exposed without any backing. Samples were exposed to a dose of at least 425 megajoules per square meter (MJ/m²) cumulative irradiance from 250-385 nm.

The change in transmission was calculated as

$$\% reduction in transmission = \frac{{T}_{Fresh} - {T}_{Aged}}{{T}_{Fresh}}$$

where T_{fresh} is the average transmission from 400-700 nm before solar aging, and T_{aged} is the average transmission from 400-700 nm after the above exposure. The results of the Solar Aging Test are summarized in the Solar Aging Results Table.

Flexibility Test: Samples were tested for flexibility by wrapping the films around a metal mandrel with a diameter of 0.5″ (1.27 cm), with the coated side facing away from the mandrel. The Spectral Properties Test was performed both before and after wrapping the samples around the mandrel. The change in spectral value in units of absolute percent was calculated as

$$\% change in spectra = {S}_{unwrapped} - {S}_{wrapped}$$

where S_{unwrapped} and S_{wrapped} are the average value of a particular spectra (e.g. transmission, reflectance, or absorption), in units of percentage, averaged over 200-700 nm, for the same sample before and after wrapping, respectively. This calculation was performed separately for the transmission, reflection, and absorption spectra. The calculated percent difference in spectra after wrapping are reported below in the Flexibility Test Results Table below.

### Test Samples

Test Sample 1: A 70 nm-thick TiO₂ layer was deposited on a silicon chip in the following manner: the vapor coater used was a Denton Vacuum Optical Coater consisting of a 5-planet planetary drive system located ˜30″ (76.2 cm) above a 4-pocket Temescal Electron Beam gun (obtained from Ferro Tec Corporation, Livermore, CA). The planetary drive system was designed to hold the substrate perpendicular to the evaporation source and to move that disk in a planetary type motion in and out of the evaporation plume during the deposition. The actual process for the coating consisted of: a) The vapor coater was vented to atmosphere and one the five planets was removed. We prepared the substrate for coating by adhering/taping it to the planet by a polyimide tape. b) The planet was reinstalled, and the other 4 planets were configured similarly, if needed, and they too were reinstalled in the coater. c) The chamber was closed and pumped to a vacuum level of <2×10⁻⁵ Torr (2.7×10⁻³ Pa). d) When the vapor coater was at a low enough vacuum, we ion beam treated the material using a Kaufman-type ion source for ˜10 minutes at a voltage of 400V as a pretreatment to the substrate for adhesion of the vapor deposited coating to the substrate prior to applying the oxide films. e) We added oxygen gas via a MKS mass flow controller (obtained from MKS Instruments, Inc., Andover, MA) to obtain a pressure of 4.0×10⁻⁵ Torr (5.3×10⁻³ Pa). This was usually about 10 standard cubic centimeters per minute (seems) for added oxygen gas. f) The planetary was started and moved around the coater at a rotational speed of ˜60 rpm to prepare for coating and to achieve a high level of uniformity on the attached substrates. g) A Temescal electron beam gun power supply was energized. A voltage of 10 kV and a current of a few milliamps was applied to the e-gun's filament, heating the source material in the e-gun. The source was heated and controlled via an Eddy Company Optical Monitoring System (OMS) (from Eddy Company, Apple Valley, CA). The source was heated until the desired deposition rate of the material was achieved; in the case of TiO₂ this rate was 2 angstroms per second (A/s), and in the case of SiO₂ this was 4 A/s. When the desired deposition rate of the material was achieved and steady, a shutter that separates the source from the planets was opened and the rate was maintained via the OMS until the desired optical thickness was achieved, at which point the shutter closed and the OMS shuts power off to the e-beam source. h) The main power to the power supply was turned off and the source allowed to cool for about 10 minutes. i) This process was repeated for additional layers/types of material until the full desired multilayer optical film had been deposited. j) The chamber was then vented back to atmospheric pressure via N₂ gas and each planet was removed and the substrate was removed from each planet.

Test Sample 2: a 115 nm-thick SiO₂ layer was deposited on a silicon chip in the same manner as Test Sample 1.

### PREPARATORY EXAMPLES

### Preparatory Example 1

Preparatory Example 1 is a THV815 film with microstructured linear prisms that was prepared as follows: A microstructured film, BEF4, was obtained to use as a mold/tooling film. The process used a three-roll vertical stack molding apparatus similar to the one described in U.S. Patent Application No. 2015/9108349 (Clarke, et al.), which includes an extruder and extrusion die adapted for extruding one or more layers of molten thermoplastic material into a mold. In this case, the mold was a microstructured tooling film (BEF4), which had been unwound onto a cylindrical roll to provide a desired surface pattern for transference to the molten thermoplastic material as it passed over the cylindrical surface of the roll. The casting roll had a surface temperature of 76.6° C. and a casting roll speed of 18.8 meters/minute. A nip force of 7600 pounds (300 pounds per linear inch) was applied to the polymer as it contacted the BEF4 film on the casting roll to produce the THV815 linear prism microstructured film (2 mil (50.8 micrometers) thick). The features of the microstructured film are reported in the Prismatic THV815 Structure Table below. Prismatic THV815 Structure Table

| | | Included | Side Wall | |
|---|---|---|---|---|
| Peak Height | Peak Pitch | Angle | Angle | Tip Radius |
| (micrometers) | (micrometers) | (degrees) | (degrees) | (micrometers) |
| 6-12 | 24 | 90 | 45 | 2-10 |

### Preparatory Example 2

Preparatory Example 2 was prepared by covering the microstructured surface of a BEF4 substrate with a stack of a base polymer layer (Layer 1), an inorganic silicon aluminum oxide (SiAlOx) barrier layer (Layer 2), and a protective polymeric layer (Layer 3) in a vacuum coater similar to the coater described in U.S. Pat. No. 5,440,446 (Shaw et al.) and U.S. Pat. No. 7,018,713 (Padiyath, et al.), both of which are incorporated herein by reference. The individual layers were formed as follows:

Layer 1 (a base polymer layer): a 356 mm wide BEF4 film of indefinite length was loaded into a roll-to-roll vacuum processing chamber. The chamber was pumped down to a pressure of 2×10⁻⁵ Torr. A web speed of 3.4 meters/minute was held while maintaining the backside of the film in contact with a coating drum chilled to −10° C. With the backside in contact with the drum, the film frontside surface was treated with a nitrogen plasma at 0.02 kW of plasma power. The film microstructured frontside surface was then coated with SR833S. The monomer was degassed under vacuum to a pressure of 20 mTorr prior to coating, loaded into a syringe pump, and pumped at a flow rate of 0.89 mL/minute and N₂ carrier gas flow rate of 60 seem through an ultrasonic atomizer operating at a frequency of 60 kHz into a heated vaporization chamber maintained at 260° C. The resulting monomer vapor stream condensed onto the film surface and was electron beam crosslinked using a multi-filament electron-beam cure gun operating at 7.0 kV and 4 mA to form a 360 nm thick base polymer layer.

Layer 2 (an inorganic layer): immediately after the base polymer layer deposition and with the backside of the film still in contact with the drum, a SiAlOx layer was sputter-deposited atop the base polymer layer. Two alternating current (AC) 40 kHz power supplies were used to control two pairs of cathodes; with each cathode housing two 90% Si/10% Al sputtering targets. During sputter deposition, the voltage signal from each power supply was used as an input for a proportional-integral-differential control loop to maintain a predetermined oxygen flow to each cathode. The sputtering conditions were: AC power 16 kW, with a gas mixture containing 350 seem argon and 213 seem oxygen at a sputter pressure of 3.5 mTorr. This provided a 18 nm thick SiAlOx layer deposited atop the base polymer layer (Layer 1).

Layer 3 (a protective polymeric layer): immediately after the SiAlOx layer deposition and with the film still in contact with the drum, a second acrylate was coated and crosslinked using the same general conditions as for Layer 1, but with these exceptions: (1) Electron beam crosslinking was carried out using a multi-filament electron-beam cure gun operated at 7 kV and 10 mA. Also, the monomer flow rate was increased to 1.33 mL/minute to provide a 535 nm acrylate layer atop Layer 3. (2) The protective polymeric layer contained 3 wt. % of DYNASYLAN 1189, with the remainder being SR833S.

### EXAMPLES

### Example 1

Example 1 was prepare as follows: A vapor coated multilayer optical film was prepared on a BEF4 substrate in the same manner as Test Sample 1, except a BEF4 film was used for the substrate, and the structure deposited on the BEF4 substrate is summarized in the Examples Structure Table below. The BEF4 substrate was taped to the planet such that the structured side of the BEF4 would be coated by the vapor coating process.

One important factor to consider when preparing vapor coatings on microstructured substrates was the geometry of the substrate. The sloped surface of the structure resulted in an increased surface area for a microstructured substrate relative to a planar substrate. As a result of this increased surface area, the same deposition process of material onto a microstructured substrate and a planar substrate resulted in a thinner coating on the surface of the microstructured substrate than on the planar substrate. In other words, the fixed deposition process deposited a fixed volume of material onto the substrates, so the substrate with higher surface area received a thinner coating overall (coating thickness equals volume of material deposited divided by surface area of substrate).

Therefore, to achieve the desired thickness on a microstructured substrate, it was necessary to increase the total volume of material deposited relative to a deposition on a planar substrate. The volume of material was increased by a factor equal to the ratio of the surface area of the microstructured substrate and the planar substrate. In the case of a BEF4 substrate, which had one-dimensional prisms with a peak angle of 90 degrees, and therefore a slope of 45 degrees, it was necessary to increase the volume of material deposited by a factor equal to 1/SIN(peak angle/2)=1/SIN(45°)=1.414.

### Example 2

Example 2 was prepared in the same manner as Example 1, except a piece of Preparatory Example 1 was used as the substrate instead of BEF4.

### Example 3

Example 3 was prepared in the same manner as Example 1, except a piece of Preparatory Example 2 was used as the substrate instead of BEF4.

### COMPARATIVE EXAMPLES

### Comparative Example 1

Comparative Example 1 was prepared in the same manner as Example 1, except a piece of BK7 was used as the substrate, and the coating layers deposited are as described in the Comparative Examples Structure Table.

### Comparative Example 2

Comparative Example 2 was a piece of BEF4 film.

### Preparatory Examples Structure Table

Layer 1 is in contact with the substrate.

| Sample | Preparatory Example 1 | Preparatory Example 2 |
|---|---|---|
| Substrate | Prismatic THV815 | BEF4 |
| Layer 1 | | SR833S/360 nm |
| Layer 2 | | SiAlOx/18 nm |
| Layer 3 | | SR833S + 3% |
| | | DYNASYLAN 1189/535 nm |

### Examples Structure Table

Layer 1 is in contact with the substrate.

| Sample | Example 1 | Example 2 | Example 3 |
|---|---|---|---|
| Substrate | BEF4 | Prismatic | BEF4 |
| | | THV815 | |
| Layer 1 | SiO₂/55.1 nm | SiO₂/55.1 nm | SR833S/360 nm |
| Layer 2 | TiO₂/31.6 nm | TiO₂/31.6 nm | SiAlOx/18 nm |
| Layer 3 | SiO₂/55.1 nm | SiO₂/55.1 nm | SR833S + 3% |
| | | | DYNASYLAN 1189/535 |
| | | | nm |
| Layer 4 | TiO₂/37.2 nm | TiO₂/37.2 nm | SiO₂/55.1 nm |
| Layer 5 | SiO₂/55.1 nm | SiO₂/55.1 nm | TiO₂/31.6 nm |
| Layer 6 | TiO₂/37.2 nm | TiO₂/37.2 nm | SiO₂/55.1 nm |
| Layer 7 | SiO₂/55.1 nm | SiO₂/55.1 nm | TiO₂/37.2 nm |
| Layer 8 | TiO₂/37.2 nm | TiO₂/37.2 nm | SiO₂/55.1 nm |
| Layer 9 | SiO₂/55.1 nm | SiO₂/55.1 nm | TiO₂/37.2 nm |
| Layer 10 | TiO₂/31.6 nm | TiO₂/31.6 nm | SiO₂/55.1 nm |
| Layer 11 | SiO₂/140.8 nm | SiO₂/140.8 nm | TiO₂/37.2 nm |
| Layer 12 | | | SiO₂/55.1 nm |
| Layer 13 | | | TiO₂/31.6 nm |
| Layer 14 | | | SiO₂/140.8 nm |

### Comparative Examples Structure Table

| | Comparative | Comparative |
|---|---|---|
| Sample | example 1 | example 2 |
| Substrate | BK7 | BEF4 |
| Layer 1 | SiO₂/58.8 nm | |
| Layer 2 | TiO₂/36.1 nm | |
| Layer 3 | SiO₂/58.8 nm | |
| Layer 4 | TiO₂/36.1 nm | |
| Layer 5 | SiO₂/58.8 nm | |
| Layer 6 | TiO₂/36.1 nm | |
| Layer 7 | SiO₂/58.8 nm | |
| Layer 8 | TiO₂/36.1 nm | |
| Layer 9 | SiO₂/58.8 nm | |
| Layer 10 | TiO₂/36.1 nm | |

### Reflection and Absorption Results Table

| | Average Reflectance | | Average Absorption | |
|---|---|---|---|---|
| | 200-400 nm (%) | | 200-400 nm (%) | |
| Sample | Measured | Modeled | Measured | Modeled |
| Example 1 | 22.4 | 41.0 | 66.2 | 50.7 |
| Example 2 | 26.6 | 41.0 | 62.9 | 50.7 |
| Example 3 | 28.3 | 41.4 | 61.5 | 50.7 |
| Comparative | 48.5 | 52.3 | 50.1 | 46.6 |
| Example 1 | | | | |
| Comparative | 6.0 | NA | 57.3 | NA |
| Example 2 | | | | |

### Transmission Results Table

| | Measured Average | Modeled Average |
|---|---|---|
| | Transmission 400-700 | Transmission 400-700 |
| Sample | nm (%) | nm (%) |
| Example 1 | 94.6 | 96.7 |
| Example 2 | 88.9 | 96.7 |
| Example 3 | 88.4 | 96.0 |
| Comparative | 64.8 | 82.6 |
| Example 1 | | |
| Comparative | 95.7 | NA |
| Example 2 | | |

### Flexibility Test Results Table

| | Measured | Measured | Measured |
|---|---|---|---|
| | Change in | Change in | Change in |
| | Average | Average | Average |
| | Transmission | Reflectance | Absorption |
| Sample | 200-700 nm (%) | 200-700 nm (%) | 200-700 nm (%) |
| Example 1 | 0.1 | −0.1 | 0.0 |
| Example 2 | −0.2 | 0.8 | −0.5 |
| Example 3 | −0.2 | −0.1 | 0.2 |
| Comparative | Not flexible enough to be wrapped around mandrel | | |
| Example 1 | | | |
| Comparative | 0.0 | 0.0 | 0.1 |
| Example 2 | | | |

### Solar Aging Results Table

| | Measured Change in Transmission | Dose |
|---|---|---|
| Sample | 400-700 nm (%) | (MJ/m²) |
| Example 1 | 9.4 | 479 |
| Example 2 | 0.4 | 479 |
| Example 3 | 5.3 | 479 |
| Comparative Example 1 | NA | NA |
| Comparative Example 2 | 22.6 | 479 |

Although specific embodiments have been illustrated and described herein, it will be appreciated by those of ordinary skill in the art that a variety of alternate and/or equivalent implementations can be substituted for the specific embodiments shown and described without departing from the scope of the present disclosure. This application is intended to cover any adaptations or variations of the specific embodiments discussed herein. Therefore, it is intended that this disclosure be limited only by the claims and the equivalents thereof.

Furthermore, all publications and patents referenced herein are incorporated by reference in their entirety to the same extent as if each individual publication or patent was specifically and individually indicated to be incorporated by reference. In the event of inconsistencies or contradictions between portions of the incorporated references and this application, the information in the preceding description. Various exemplary embodiments have been described. These and other embodiments are within the scope of the following claims.

1. A structured ultraviolet light shielding article comprising:
a) a microstructured film comprising a first major surface and an opposing second major surface, wherein the first major surface comprises a plurality of microstructures projecting therefrom, wherein at least some of the plurality of microstructures each has a surface whose slope causes light that is normally incident to the first major surface of the microstructured film to intercept the first major surface or the surface of at least one other microstructure after reflection; and
b) a multilayer optical film disposed on the plurality of microstructures, wherein the multilayer optical film is comprised of one or more alternating first and second inorganic optical layers collectively reflecting and absorbing light that is normally incident to the first major surface of the microstructured film, an average of at least 50, 60, 70, 80, 90, or 95 percent of incident ultraviolet light over at least a 30-nanometer wavelength reflection bandwidth in a wavelength range from 190 nanometers (nm) to 400 nm.

2. The structured ultraviolet light shielding article of claim 1, wherein the plurality of microstructures have an aspect ratio of height to width of no more than 10:1, 8:1, 6:1, 4:1, 2:1, or 1:1.

3. The structured ultraviolet light shielding article of claim 1, wherein at least some of the microstructures comprise at least one angled sidewall that has a peak that comes to a point.

4. The structured ultraviolet light shielding article of claim 1, wherein at least some of the microstructures comprise at least one angled sidewall having a peak angle of 90 degrees or less.

5. The structured ultraviolet light shielding article of claim 1, wherein at least some of the microstructures have a shape with a triangular cross-section.

6. The structured ultraviolet light shielding article of claim 1, wherein the microstructures have a shape that is a prism, a pyramid, an inverted pyramid, a diffraction grating, an inverted cone, or a cone.

7. The structured ultraviolet light shielding article of claim 1, wherein each of the microstructures has the same size and shape.

8. The structured ultraviolet light shielding article of claim 1, wherein the microstructured film is flexible.

9. The structured ultraviolet light shielding article of claim 1, wherein the microstructures have a height of 0.5 micrometer to 500 micrometers.

10. The structured ultraviolet light shielding article of claim 1, wherein the peak angle is 5, 15, 25, 35, or 45 degrees or greater.

11. The structured ultraviolet light shielding article of claim 1, wherein each of the first and second optical layers independently has a thickness of 20 nm to 400 nm.

12. The structured ultraviolet light shielding article of claim 1, wherein the alternating first and second inorganic optical layers collectively transmit light that is normally incident to the first major surface of the microstructured film, an average of at least 50, 60, 70, 80, 90, or 95 percent of incident visible light in a wavelength range from greater than 400 nm to 700 nm.

13. The structured ultraviolet light shielding article of claim 1, wherein the first optical layer comprises at least one of niobium oxide, titanium oxide, silicon oxynitride, molybdenum oxide, tungsten oxide, silicon nitride, indium tin oxide, hafnium oxide, tantalum oxide, zirconium oxynitride, zirconium oxide, aluminum zinc oxide, or zinc oxide and wherein the second optical layer comprises at least one of silicon oxide, silicon aluminum oxide, N type- or P type-doped silicon oxide, aluminum oxide, aluminum fluoride, magnesium fluoride, calcium fluoride, indium tin oxide, or zinc oxide.

14. The structured ultraviolet light shielding article of claim 1, wherein the first optical layer comprises at least one of niobium oxide or titanium oxide, and wherein the second optical layer comprises silicon aluminum oxide.

15. The structured ultraviolet light shielding article of claim 1, wherein the outermost optical layer is a second optical layer and has a thickness of at least 70 nm.

16. The structured ultraviolet light shielding article of claim 1, wherein at least one of the first optical layers nearest to the exterior of the film or nearest to the microstructures has a thickness of at most 95%, 90%, 85%, or at most 80% of the other first optical layers.

17. The structured ultraviolet light shielding article of claim 1, wherein the multilayer optical film is formed of at least 1 first optical layer and 2 second optical layers.

18. The structured ultraviolet light shielding article of claim 1, which transmits light that is normally incident to the first major surface of the microstructured film, an average of at least 50, 60, 70, 80, 90, or 95 percent of normally incident visible light in a wavelength range from greater than 400 nm to 700 nm.

19. The structured ultraviolet light shielding article of claim 1, further comprising a barrier coating disposed between the plurality of microstructures and the multilayer optical film, the barrier coating comprising: at least one dyad comprised of a (co)polymer layer overlaying the first major surface of the microstructured film and an inorganic layer overlaying the (co)polymer layer; and an outer (co)polymer layer overlaying the at least one dyad; and optionally, at least one outer inorganic layer overlaying the outer (co)polymer layer.

20. The structured ultraviolet light shielding article of claim 1, exhibiting an average transmission of wavelengths between 400 nm and 700 nm through the article that is reduced by less than 20%, 10%, 5%, or less than 1% after exposure to a certain dose of ultraviolet light.

21. A solar array comprising the structured ultraviolet light shielding article of claim 1 disposed on an exterior surface of the solar array.
